(19) United States
(12) Patent Application Publication
(10) Pub. No.: US 2020/0161532 A1
(43) Pub. Date: May 21, 2020

(54) TRANSDUCER DEVICE, JOINT DEVICE, AND ACTUATOR DEVICE

(71) Applicant: SONY CORPORATION, TOKYO (JP)

(72) Inventors: KAZUHITO WAKANA, KANAGAWA (JP); SATOSHI NAKAMARU, KANAGAWA (JP); AKIHIRO NAKATA, KANAGAWA (JP); HIROICHI ISHIKAWA, TOKYO (JP); TOMOMI YUKUMOTO, CHIBA (JP)

(21) Appl. No.: 16/627,147

(22) PCT Filed: May 17, 2018
(86) PCT No.: PCT/JP2018/019135

§ 371 Date: Dec. 27, 2019

(30) Foreign Application Priority Data
Jul. 6, 2017 (JP) 2017-133160

(51) Int. Cl. H01L 41/09; B25J 17/00; B25J 19/00; H01L 41/047; H01L 41/193; H01L 41/113; H01L 41/45; H04R 19/02

(52) U.S. Cl. CPC H01L 41/0986; B25J 17/00; B25J 19/0008; H04R 19/02; H01L 41/193; H01L 41/113; H01L 41/45; H01L 41/0478

(57) ABSTRACT

A transducer device using an electroactive polymer is provided. The transducer device has a predetermined driving direction and includes: a laminate of elastomer actuators that is disposed so as to be inclined at a predetermined angle with respect to the driving direction and has a stretchable elastomer and a following electrode; and a fixed frame unit and a drive frame unit that support the laminate. The fixed frame unit supports one end of the laminate, and the drive frame unit supports the other end of the laminate, faces the fixed frame unit, and is movable in the driving direction with respect to the fixed frame unit.

### TECHNICAL FIELD

The technology disclosed herein relates to a transducer device, a joint device, and an actuator device using an electro-active polymer such as a dielectric elastomer.

### BACKGROUND ART

An electro-active polymer (EAP) is a polymer that can repeatedly undergo deformation such as extension, contraction, and bending by electrical stimulation. Among electroactive polymers, a ferroelectric polymer and a dielectric elastomer are mainly used. Examples of the dielectric elastomer include a silicon polymer, a urethane polymer, an acrylic polymer, and the like.

In a strong electric field, a dielectric elastomer has the property of contracting in the direction of the electric field due to Coulomb force and extending in a direction perpendicular to the electric field. Taking advantage of such properties, actuators and transducers using dielectric elastomers have been developed (for example, refer to Patent Documents 1 and 2).

A dielectric elastomer actuator has, for example, a capacitor having elasticity with a dielectric elastomer sandwiched between two flexible or deformable electrodes as a basic structure. When a voltage is applied to such a capacitor, an attractive force is generated between the electrodes to crush the dielectric elastomer, and the dielectric elastomer itself is compressed by electrostatic force. As a result, a pressure stronger than the Coulomb force acts between the electrodes, and the dielectric elastomer extends in a planar direction.

In principle, a dielectric elastomer actuator can output a stroke, driving speed, and generated force equivalent to or higher than those of a human muscle, and has excellent characteristics as a linear actuator.

However, in many of the dielectric elastomer actuators currently known (or as of filing of the present application), the generated force depends only on the cross-sectional area perpendicular to the driving direction and does not depend on the length as seen in the driving direction. For example, the force generated in a perpendicular direction of a dielectric elastomer actuator including a capacitor structure in which dielectric elastomers are alternately laminated with two electrodes depends on the area of the electrode under an environment with a predetermined applied electric field strength but does not depend on the total thickness of the laminated elastomers. That is, even if the number of laminated layers is increased and the length as seen in the perpendicular direction of the actuator is increased, the generated force cannot be improved.

For example, in the case of assuming that a dielectric elastomer actuator is applied to an elongated mechanism such as an endoscope or an end effector of a robot arm, the effective cross-sectional area of the dielectric elastomer that contributes to the generated force (in the above case, the cross-sectional area orthogonal to the driving direction of the actuator) cannot be sufficiently ensured. Thus, the necessary generated force for driving the endoscope or the end effector may not be obtained.

### CITATION LIST

### Patent Document

Patent Document 1: Japanese Patent Application Laid-Open No. 2006-520180

Patent Document 2: US Patent Publication No. 2009/0085444

### SUMMARY OF THE INVENTION

### Problems to be Solved by the Invention

An object of the technology disclosed herein is to provide a transducer device, a joint device, and an actuator device using an electro-active polymer such as a dielectric elastomer.

### Solutions to Problems

The technology disclosed herein has been made in consideration of the above problems. A first aspect thereof is a transducer device that has

a predetermined driving direction and

includes:

a laminate of elastomer actuators that is disposed so as to be inclined at a predetermined angle with respect to the driving direction and has a stretchable elastomer and a following electrode; and

a fixed frame unit and a drive frame unit that support the laminate.

In this configuration, the fixed frame unit supports one end of the laminate. In addition, the drive frame unit supports the other end of the laminate, faces the fixed frame unit, and is movable in the driving direction with respect to the fixed frame unit.

For example, the transducer device includes a pair of laminates of a feather-like structure in which the drive frame unit supports each one end of first and second laminates inclined at the predetermined angle on both sides, and the fixed frame unit supports the other ends of the first and second laminates.

Alternatively, the transducer device has prism shape in which the drive frame unit includes an N-facet prism (where N is an integer of 3 or larger) having a central axis in the driving direction, the fixed frame unit includes a hollow N-facet prism that accommodates the drive frame unit, and each one of the N laminates is supported by each outer wall surface of the drive frame unit and an inner wall surface of the fixed frame unit opposed to the drive frame unit.

Alternatively, the transducer device is configured such that the laminate is formed by laminating a plurality of the elastomer actuators that includes the trapezoidal elastomer and the following electrode, and the outer wall surfaces of the drive frame unit support the laminate by one end corresponding to an upper base of the trapezoid, and the inner wall surface of the opposing fixed frame unit supports the laminate by one end corresponding to a lower base of the trapezoid.

In addition, a second aspect of the technology disclosed herein is a joint device that includes:

a transducer unit that has a laminate of elastomer actuators that is disposed so as to be inclined at a predetermined angle with respect to a predetermined driving direction and includes a stretchable elastomer and a following electrode, and a fixed frame unit and a drive frame unit that support the laminate;

a transfer unit that is attached to the drive frame unit and transfers a movement operation of the drive frame unit with respect to the fixed frame unit in the driving direction; and

a movable unit that is pulled by the transfer unit.

Further, a third aspect of the technology disclosed herein is an actuator device that includes:

a transducer unit that has a laminate of elastomer actuators that is disposed so as to be inclined at a predetermined angle with respect to a predetermined driving direction and includes a stretchable elastomer and a following electrode, and a fixed frame unit and a drive frame unit that support the laminate;

a wire with one end attached to the drive frame unit; and

a spring that fixes a portion of the wire and applies a predetermined tension to the wire.

### Effects of the Invention

According to the technology disclosed in this specification, it is possible to provide a transducer device, a joint device, and an actuator device using an electro-active polymer such as a dielectric elastomer.

Note that advantageous effects described herein are mere examples and the advantageous effects of the present invention are not limited to them. Furthermore, in some cases, the present invention may have further advantageous effects in addition to the foregoing ones.

Other objects, features, and advantages of the technique disclosed herein will be clarified by more detailed descriptions based on embodiments below and the accompanying drawings.

### BRIEF DESCRIPTION OF DRAWINGS

FIG. 1 is a diagram showing a basic structure of a transducer device 100 proposed herein.

FIG. 2 is a perspective view of the transducer device 100.

FIG. 3 is a diagram showing the transducer device 100 before and after driving.

FIG. 4 is a diagram showing a DEA effective cross-sectional area S of the transducer device 100.

FIG. 5 is a diagram showing a relationship between a generated force F of the transducer device 100 and an inclination angle θ between a driving direction and a dielectric elastomer actuator laminate 101.

FIG. 6 is a diagram showing a modified example 600 of a transducer device having a driving direction inclined at a predetermined angle θ from a direction in which dielectric elastomer actuators extend.

FIG. 7 is a diagram showing another modified example 700 of a transducer device having a driving direction inclined at a predetermined angle θ from a direction in which dielectric elastomer actuators extend.

FIG. 8 is a diagram showing still another modified example 800 of a transducer device having a driving direction inclined at a predetermined angle θ from a direction in which dielectric elastomer actuators extend.

FIG. 9 is a diagram for describing a generated force of a rectangular dielectric elastomer actuator 900.

FIG. 10 is a diagram for describing a generated force of a trapezoidal dielectric elastomer actuator 1000.

FIG. 11 is a diagram showing still another modified example 1100 of a transducer device having a driving direction inclined at a predetermined angle θ from a direction in which dielectric elastomer actuators extend.

FIG. 12 is a diagram showing a cross-sectional structure of a truncated cone-shaped dielectric elastomer actuator 1200.

FIG. 13 is a diagram showing a configuration example 1300 of a joint bending mechanism that has a transducer device driven by dielectric elastomer actuator laminates of a feather-like structure.

FIG. 14 is a diagram showing how the joint bending mechanism 1300 operates.

FIG. 15 is a diagram showing a configuration example 1500 of a bending mechanism that has a transducer device driven by dielectric elastomer actuator laminates of a feather-like structure.

FIG. 16 shows how the bending mechanism 1500 operates.

FIG. 17 is a diagram showing a configuration example 1700 of a linear actuator device that has a transducer device driven by a dielectric elastomer actuator laminate of a feather-like structure.

FIG. 18 is a diagram showing how the configuration example 1700 of the linear actuator device operates.

FIG. 19 is a diagram showing another configuration example 1900 of a linear actuator device that has a transducer device driven by a dielectric elastomer actuator laminate of a feather-like structure.

FIG. 20 is a diagram showing how the configuration example 1900 of the linear actuator device operates.

FIG. 21 is a diagram showing a configuration example 2100 of a vibration presentation device that has transducer devices driven by dielectric elastomer actuator laminates of a feather-like structure.

FIG. 22 is a diagram showing.

FIG. 23 is a diagram showing a configuration example of a transducer device 2300.

FIG. 24 is a diagram showing a DEA effective cross-sectional area S of the transducer device 2300.

FIG. 25 is a diagram showing a configuration example of a transducer device 2500.

FIG. 26 is a diagram showing a DEA effective cross-sectional area S of the transducer device 2500.

FIG. 27 is a diagram showing a configuration example of a dielectric elastomer actuator 2700 using a dielectric elastomer.

### MODES FOR CARRYING OUT THE INVENTION

Hereinafter, embodiments of the technique disclosed herein will be described with reference to the drawings.

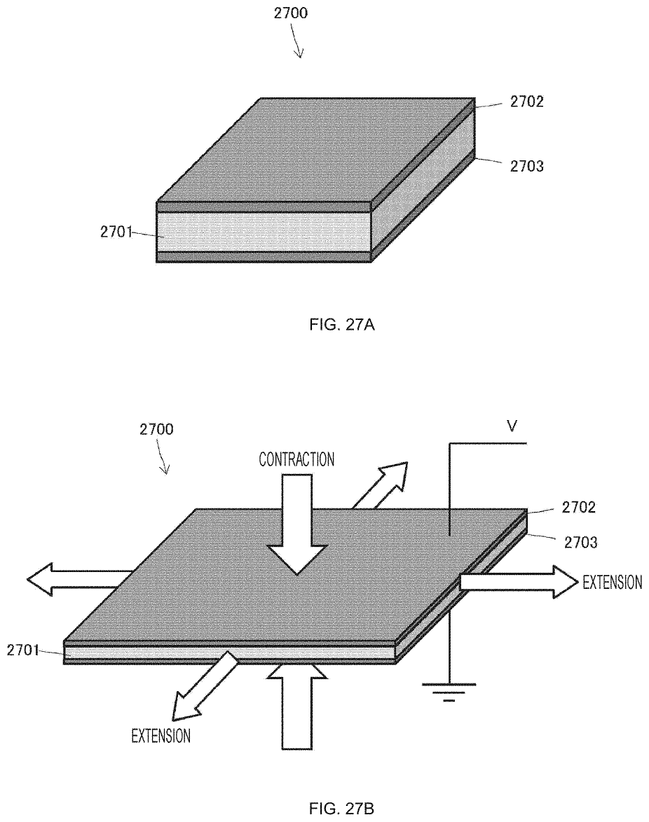

In a strong electric field, a dielectric elastomer has the property of contracting in the direction of the electric field due to Coulomb force and extending in a direction perpendicular to the electric field. FIG. 27 shows a configuration example of a dielectric elastomer actuator 2700 using a dielectric elastomer.

As shown in FIG. 27(A), the dielectric elastomer actuator 2700 has a capacitor structure in which the upper and lower surfaces of a film- or sheet-like thin dielectric elastomer 2701 are sandwiched between two electrodes 2702 and 2703. Each of the electrodes 2702 and 2703 is a flexible electrode that can be deformed following the deformation of the dielectric elastomer 2701. Hereinafter, a flexible electrode that follows the deformation of the dielectric elastomer will be also referred to as a “following electrode”.

As shown in FIG. 27(B), when a voltage V is applied between the electrodes 2702 and 2703, positive charges are accumulated on one electrode 2702, and an attached electrode is accumulated on the other electrode 2703. Thus, the dielectric elastomer 2701 is crushed by attractive forces generated between the electrodes 2702 and 2703. In addition, the dielectric elastomer 2701 itself contracts in the direction of the electric field and extends in the direction perpendicular to the electric field due to electrostatic force, and the electrodes 2702 and 2703 also deform following the dielectric elastomer 2701. As a result, the dielectric elastomer actuator 2700 of a thin structure contracts in the perpendicular direction (the direction of normal to the plane) and extends in the in-plane direction (the direction horizontal to the plane).

It is expected that the amount of deformation (stroke) and the generated force will be improved by laminating the planar dielectric elastomer actuators as shown in FIG. 27.

FIG. 23 shows a configuration example of a transducer device 2300 using a laminate of dielectric elastomer actuators. Specifically, FIG. 23(A) shows the dielectric elastomer actuator 2300 in an initial state (where no voltage is applied), and FIG. 23(B) shows the dielectric elastomer actuator 2300 in an extended state (where a voltage is applied).

The illustrated transducer device 2300 includes an elongated dielectric elastomer actuator laminate 2301, and a fixed frame unit 2302 and a drive frame unit 2303 each supporting both ends of the dielectric elastomer actuator laminate 2301 as seen from the longitudinal direction (or driving direction).

The dielectric elastomer actuator laminate 2301 is formed by laminating a plurality of thin dielectric elastomer actuators in the perpendicular direction (or in the thickness direction of the dielectric elastomer). Each dielectric elastomer actuator is basically structured as shown in FIG. 27.

The laminating direction of the dielectric elastomer actuator laminate 2301 is orthogonal to the driving direction. The longitudinal dimension of the dielectric elastomer actuator laminate 2301 is designated as L, the width of the dielectric elastomer actuator laminate 2301 as W, and the height of the dielectric elastomer actuator laminate 2301 as H. L and W each correspond to the size of each dielectric elastomer actuator used. L also corresponds to the distance between the fixed frame unit 2302 and the drive frame unit 2303. In addition, H corresponds to the thickness obtained by laminating the plurality of dielectric elastomer actuators. Further, note that the dielectric elastomer actuator laminate 2301 is arbitrarily structured. For example, a laminated structure can be made by repeatedly folding a dielectric elastomer sheet with following electrodes on both sides.

The fixed frame unit 2302 and the drive frame unit 2303 are attached to both end edges of each laminated dielectric elastomer actuator so as to be opposed to each other. Strictly speaking, the fixed frame unit 2302 and the drive frame unit 2303 are disposed in the perpendicular direction of each of the dielectric elastomer actuators (or in the direction parallel to the laminating direction). The fixed frame unit 2302 and the drive frame unit 2303 are mechanically or chemically coupled to the dielectric elastomer actuators.

The position of the fixed frame unit 2302 is fixed. On the other hand, the drive frame unit 2303 can move relative to the fixed frame unit 2302. The direction in which the drive frame unit 2303 moves relative to the fixed frame unit 2302 is the driving direction of the transducer device 2300. Specifically, the drive frame unit 2303 is given a degree of freedom to make a translational movement in the direction away from the fixed frame unit 2302 along the longitudinal direction of the dielectric elastomer actuator laminate 2301. Therefore, in the transducer device 2300, the direction of extension in the longitudinal direction of the dielectric elastomer actuator laminate 2301 is the driving direction. In addition, as described above, the support structure for supporting the fixed frame unit 2302 and the drive frame unit 2303 can be arbitrarily set and is not illustrated in FIG. 23.

When a voltage is synchronously applied to the electrode of each of the dielectric elastomer actuators constituting the dielectric elastomer actuator laminate 2301, each dielectric elastomer actuators synchronously contracts in the perpendicular direction and extends in the in-plane direction. As described above, the driving of the drive frame unit 2303 is limited to the extension only in the longitudinal direction of the dielectric elastomer actuator laminate 2301. Therefore, when the dielectric elastomer actuators constituting the dielectric elastomer actuator laminate 2301 extend in the in-plane direction by voltage application, the drive frame unit 2303 makes a translational movement in the direction in which the dielectric elastomer actuator laminate 2301 extends in the longitudinal direction. This is the driving of the transducer device 2300. The transducer device 2300 is driven (extends) by using the extension of the dielectric elastomer actuators used in the in-plane direction, and can thus be called “in-plane drive type”.

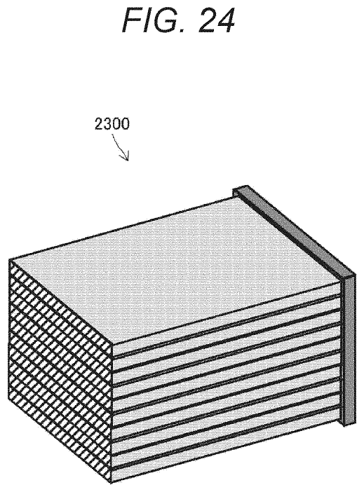

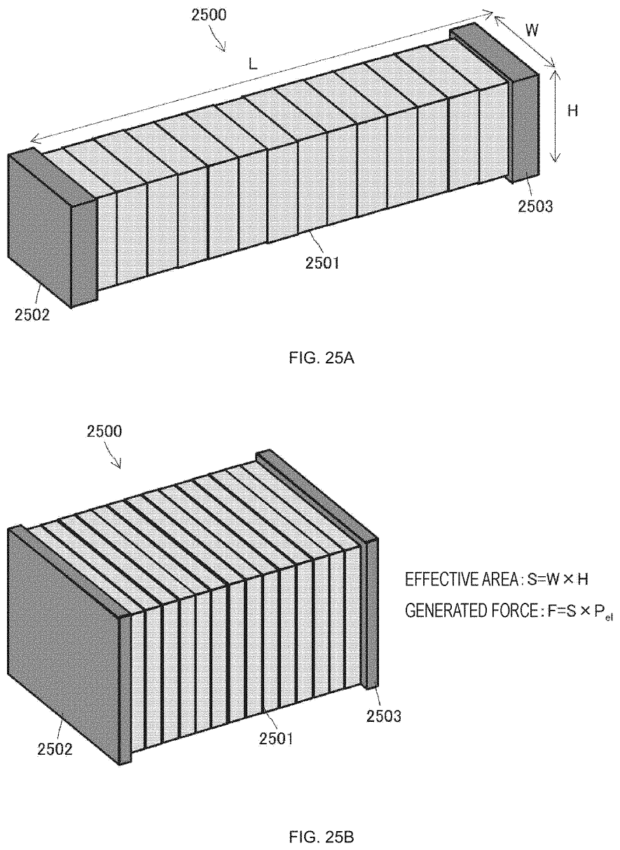

In the case of the transducer device 2300, the dielectric elastomer actuator (DEA) effective cross-sectional area S of the dielectric elastomers that contribute to the generated force is a cross-sectional area W×H orthogonal to the longitudinal direction that is the driving direction of the dielectric elastomer actuator laminate 2301. In FIG. 24, the DEA effective cross-sectional area S of the dielectric elastomer actuator laminate 2301 used in the transducer device 2300 is indicated by hatching. The generated force F of the transducer device 2300 is S×Pₑₗ where Pₑₗ represents the generated stress due to the Coulomb force acting between the electrodes.

[Equation 1]

Effective cross-sectional area: S=W×H

Generated force: F=S×Pₑₗ (1)

Therefore, in the transducer device 2300, when the dimension L in the longitudinal direction (that is, the driving direction) of the dielectric elastomer actuator laminate 2301 is increased, the generated force F is not improved even though the stroke of the dielectric elastomer actuator 2300 can be made larger.

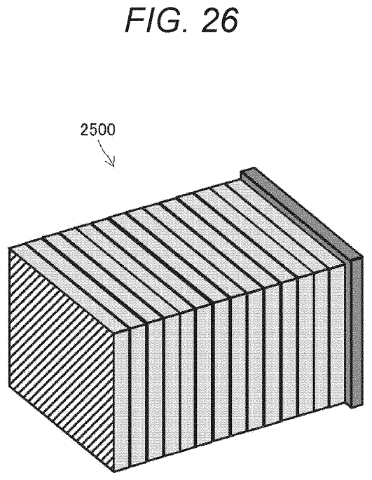

In addition, FIG. 25 shows another configuration example 2500 of a transducer device using a laminate of dielectric elastomer actuators. Specifically, FIG. 25(A) shows the transducer device 2500 in an initial state (no voltage is applied), and FIG. 25(B) shows the transducer device 2500 at the time of driving (a state where voltage is applied).

The illustrated transducer device 2500 includes an elongated dielectric elastomer actuator laminate 2501, and a fixed frame unit 2502 and a drive frame unit 2503 each supporting both ends of the dielectric elastomer actuator laminate 2501 as seen from the longitudinal direction.

The dielectric elastomer actuator laminate 2501 is formed by laminating a plurality of thin dielectric elastomer actuators in the perpendicular direction (or in the thickness direction of the dielectric elastomer). Each dielectric elastomer actuator is basically structured as shown in FIG. 27.

A large number of dielectric elastomer actuators are laminated in the longitudinal direction of the dielectric elastomer actuator laminate 2501. Therefore, when the longitudinal direction of the dielectric elastomer actuator laminate 2501 is set as a driving direction, the driving direction coincides with the laminating direction. The longitudinal dimension of the dielectric elastomer actuator laminate 2501 is designated as L, the width of the dielectric elastomer actuator laminate 2501 as W, and the height of the dielectric elastomer actuator laminate 2501 as H. L corresponds to the thickness obtained by laminating the plurality of dielectric elastomer actuators. In addition, L also corresponds to the distance between the fixed frame unit 2502 and the drive frame unit 2503. W and H respectively correspond to the width and height of each dielectric elastomer actuator used. Further, the dielectric elastomer actuator laminate 2501 is arbitrarily structured. For example, a laminated structure can be made by repeatedly folding a dielectric elastomer sheet with following electrodes on both sides.

The fixed frame unit 2502 and the drive frame unit 2503 are attached to both end edges in the longitudinal direction of the dielectric elastomer actuator laminate 2501 so as to be opposed to each other. That is, the fixed frame unit 2502 and the drive frame unit 2503 are disposed in a direction orthogonal to the laminating direction (or a direction parallel to the in-plane direction of each laminated dielectric elastomer actuator). The position of the fixed frame unit 2502 is fixed. On the other hand, the drive frame unit 2503 can move relative to the fixed frame unit 2502. The direction in which the drive frame unit 2503 makes a translational movement relative to the fixed frame unit 2502 is the driving direction of the transducer device 2500.

When a voltage is synchronously applied to the electrode of each of the dielectric elastomer actuators constituting the dielectric elastomer actuator laminate 2501, each dielectric elastomer actuator synchronously extends in the in-plane direction and contracts in the perpendicular direction. As a result, the drive frame unit 2503 makes a translational movement in the direction in which the dielectric elastomer actuator laminate 2501 contracts in the longitudinal direction, and this is the driving of the transducer device 2500. The transducer device 2500 is driven (extends) by using the contraction of the dielectric elastomer actuators used in the perpendicular direction, and can thus be called “perpendicular drive type”.

In the case of the transducer device 2500, the DEA effective cross-sectional area S of the dielectric elastomers that contribute to the generated force is the area of the dielectric elastomer sheet perpendicular to the longitudinal direction of the dielectric elastomer sheet layer 2501 (in other words, the areas of the electrodes 2502 and 2503) W×H. In FIG. 26, the DEA effective cross-sectional area S of the transducer device 2500 is indicated by hatching. The generated force F is S×Pₑₗ where Pₑₗ represents the generated force due to the Coulomb force acting between the electrodes.

[Equation 2]

Effective cross-sectional area: S=W×H

Generated force: F=S×Pₑₗ (2)

Therefore, in the transducer device 2500, when the number of the dielectric elastomer sheets to be laminated is increased to increase the thickness of the dielectric elastomer sheet layer 2501 (that is, the dimension as seen from the driving direction) L, the generated force F is not improved even though the stroke of the dielectric elastomer actuator 2500 can be made larger.

In short, in either the in-plane drive type transducer device shown in FIG. 23 or the perpendicular drive type transducer device shown in FIG. 25, the generated force does not increase even if the dimension is increased in the driving direction. In other words, in a case where the transducer device is used in a space that is long in the driving direction but has a small cross section orthogonal to the driving direction, sufficient generated force may not be obtained.

Therefore, there will be proposed hereinafter a transducer device using a laminate of dielectric elastomer actuators having a structure in which the generated force is improved by increasing the dimension in the driving direction. Such a transducer device can provide a sufficient generated force even in a space that is long in the driving direction but has a small cross-sectional size orthogonal to the driving direction.

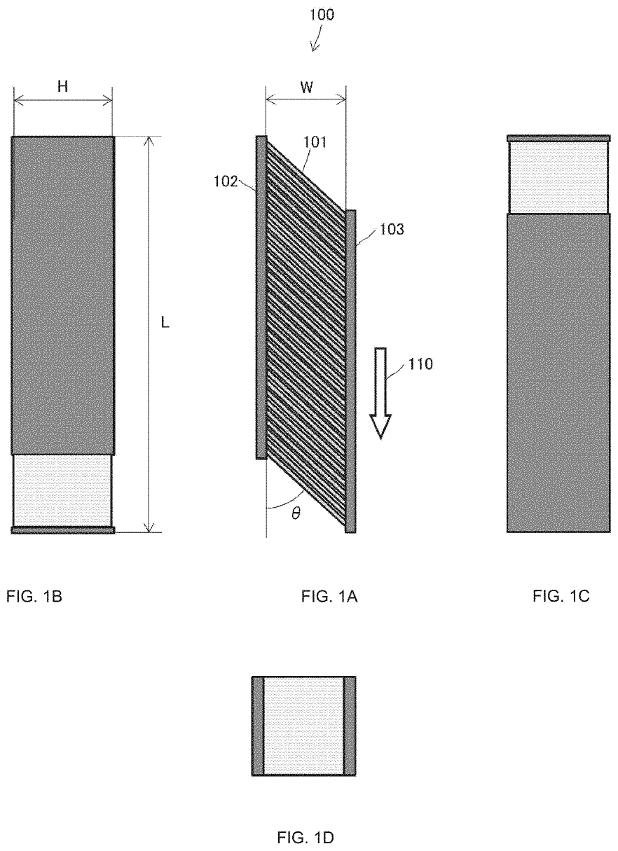

FIG. 1 shows a basic structure of a transducer device 100 proposed herein. Specifically, FIG. 1(A) is a front view in which the side edges of each dielectric elastomer actuator constituting the dielectric elastomer actuator laminate 101 can be seen, FIG. 1(B) is a side view seen from the fixed frame unit 102 side, FIG. 1(C) is a side view seen from the drive frame unit 103 side, and FIG. 1(D) is a side view seen from the driving direction. In addition, FIG. 2 is a perspective view of the transducer device 100.

The transducer device 100 includes a dielectric elastomer actuator laminate 101, and a fixed frame unit 102 and a drive frame unit 103 each supporting both ends of the dielectric elastomer actuator laminate 101. Further, the transducer device 100 has a driving direction indicated by reference number 110. The dielectric elastomer actuator laminate 101 is disposed so as to be inclined at a predetermined angle θ with respect to the driving direction 110.

The dielectric elastomer actuator laminate 101 is formed by laminating a plurality of thin dielectric elastomer actuators in the perpendicular direction (or in the thickness direction of the dielectric elastomer actuators). Each dielectric elastomer actuator is basically structured as shown in FIG. 27. The fixed frame unit 102 and the drive frame unit 103 are mechanically or chemically coupled to each of the dielectric elastomer actuators.

The inclination of the dielectric elastomer actuator laminate 101 at a predetermined angle θ with respect to the driving direction 110 means that each dielectric elastomer actuator is laminated in a direction inclined at the predetermined angle θ with respect to the driving direction 110, or that the thickness direction of each dielectric elastomer actuator is inclined at a predetermined angle θ with respect to the driving direction 110.

As can be seen from FIG. 1(A), the transducer device 100 has a half-feather-like structure. That is, the drive frame unit 103 corresponds to a quill, and the dielectric elastomer actuator laminate 101 corresponding to a vane is attached to only one side of the quill. Here, the longitudinal dimension of the dielectric elastomer actuator laminate 101 is designated as L, the height of each laminated dielectric elastomer actuator as H, and the distance between the fixed frame unit 102 and the drive frame unit 103 as W.

The position of the fixed frame unit 102 is fixed. On the other hand, the drive frame unit 103 can move relative to the fixed frame unit 102. The driving direction 110 of the transducer device 100 is a direction in which the drive frame unit 103 moves relative to the fixed frame unit 102. Specifically, the fixed frame unit 102 and the drive frame unit 103 are arranged so as to be parallel to each other. The driving direction 110 is a direction in which the drive frame unit 103 makes a translational movement in its in-plane direction while keeping the constant distance W to the fixed frame unit 102.

For example, it is assumed that the drive frame unit 103 is supported by a support structure such as a guide rail for restricting displacement in the driving direction 110. However, the respective support structures each supporting the fixed frame unit 102 and the drive frame unit 103 can be arbitrarily set and are not illustrated in FIG. 1.

When a voltage is synchronously applied to the electrode of each of the dielectric elastomer actuators constituting the dielectric elastomer actuator laminate 101, each dielectric elastomer actuators synchronously contracts in the perpendicular direction and extends in the in-plane direction.

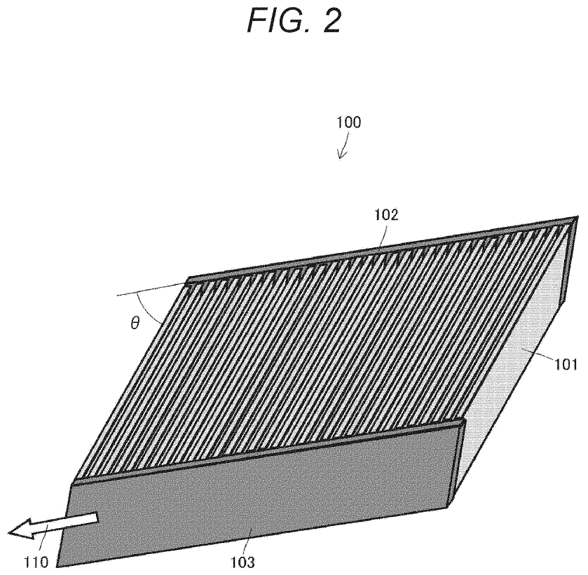

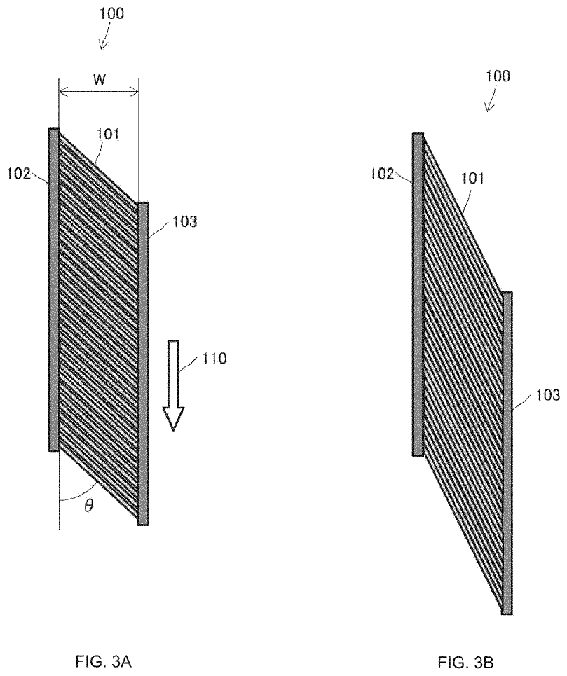

As described above, the drive frame unit 103 is given a degree of freedom to make a translational movement in the driving direction 110 while keeping the constant distance W to the fixed frame unit 102. Therefore, when the dielectric elastomer actuators constituting the dielectric elastomer actuator laminate 101 extend in the in-plane direction by voltage application, the drive frame unit 103 moves relative to the fixed frame unit 102 in the driving direction 110 inclined at a predetermined angle θ from the extending direction. This is the driving of the transducer device 100. FIG. 3(A) shows the transducer device 100 before driving (a state where no voltage is applied), and FIG. 3(B) shows the transducer device 100 after driving (a state where voltage is applied).

The transducer device 2300 shown in FIG. 23 has the direction parallel to the in-plane direction of the dielectric elastomer actuators used as the driving direction, and the transducer device 2500 shown in FIG. 25 has the direction perpendicular to the dielectric elastomer actuators used (or the laminating direction) as the driving direction. On the other hand, the transducer device 100 shown in FIG. 1 has one major feature in that the driving direction 110 is the direction inclined at the predetermined angle θ with respect to the in-plane direction of the dielectric elastomer actuators used. Such a feature is achieved by the fixed frame unit 102 and the drive frame unit 103 supporting the dielectric elastomer actuator laminate 101 at an inclination of the predetermined angle θ with respect to the driving direction 110.

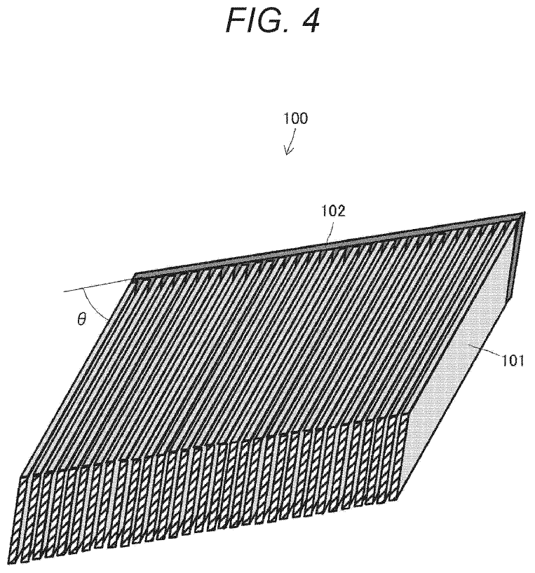

In the case of the transducer device 100, the DEA effective cross-sectional area S of the dielectric elastomers that contribute to the generated force is (L−W tan θ)×cos θ×H. In FIG. 4, the DEA effective cross-sectional area S of the transducer device 100 is indicated by hatching. The generated force F of the transducer device 100 is S×Pₑₗ×cos θ where Pₑₗ represents the generated stress due to the Coulomb force acting between the electrodes.

[Equation 3]

Effective cross-sectional area: S=(L−W tan θ)×sin θ×H

Generated force: F=S×Pₑₗ×cos θ (3)

As can be seen from FIGS. 1 to 3, in the transducer device 100, each laminated dielectric elastomer actuator is attached to the fixed frame unit 102 and the drive frame unit 103 so as to be inclined at the predetermined angle θ with respect to the driving direction 110. Accordingly, the force of contraction of each laminated dielectric elastomer actuator in the perpendicular direction is extracted as the force generated in the driving direction, and thus the efficiency is slightly lowered. However, as can be seen from the above equation (3), the DEA effective cross-sectional area of the transducer device 100 is proportional to the dimension L of the dielectric elastomer actuator laminate 101 as seen in the longitudinal direction (that is, the driving direction 110). Therefore, the generated force of the transducer device 100 can be improved by increasing the dimension L of the dielectric elastomer actuator laminate 101.

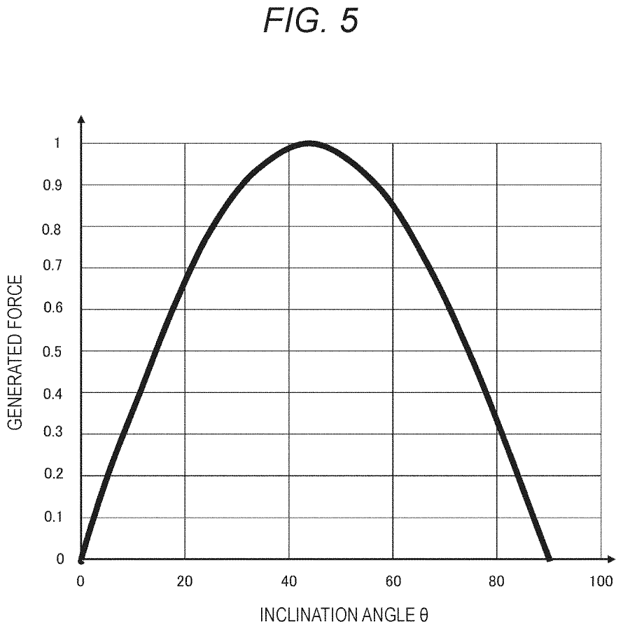

FIG. 5 shows a relationship between the generated force F of the transducer device 100 shown in FIG. 1 and the inclination angle θ between the fixed frame unit 102, the drive frame unit 103 (or the driving direction) and the dielectric elastomer actuator laminate 101. However, in FIG. 5, the horizontal axis indicates the inclination angle θ, and the vertical axis indicates the generated force. However, the vertical axis indicates the generated force that is normalized with a maximum value of 1. In the example shown in FIG. 5, the generated force of the transducer device 100 can be maximized at the inclination angle θ of 45°.

In short, with the generated force F also depending on the length L as seen in the driving direction, the transducer device 100 can be said as an actuator unit that can efficiently obtain the output even in a limited space that is long in the driving direction but has a small cross section orthogonal to the driving direction. Therefore, for example, the transducer device 100 can be also suitably applied to an elongated mechanism such as an endoscope or an end effector of a robot arm.

In addition, the length L of the transducer device 100 as seen in the driving direction is preferably at least three times the minimum distance W at the place where the fixed frame unit 102 and the drive frame unit 103 sandwich the dielectric elastomer actuator laminate 101. First example

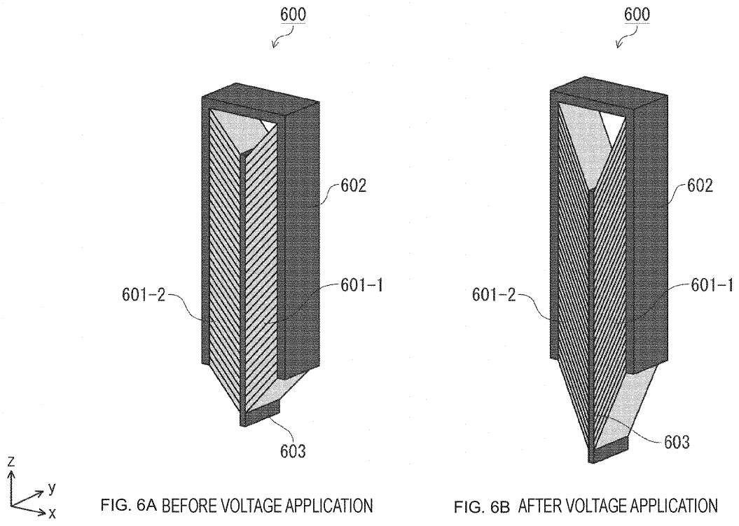

FIG. 6 shows a modified example 600 of a transducer device having a driving direction inclined at a predetermined angle θ from a direction in which a dielectric elastomer actuator extends.

The transducer device 100 shown in FIGS. 1 to 4 has a half-feather-like structure in which the dielectric elastomer actuator laminate 101 inclined at the predetermined angle θ with respect to the driving direction 110 is attached to one side of the drive frame unit 103 and is sandwiched between the drive frame unit 103 and the opposing fixed frame unit 102. That is, the drive frame unit 103 corresponds to a quill, and the dielectric elastomer actuator laminate 101 corresponding to a vane is attached to only one side of the quill.

On the other hand, the transducer device 600 shown in FIG. 6 has a feather-like structure in which a first dielectric elastomer actuator laminate 601-1 and a second dielectric elastomer actuator laminate 601-2 each inclined at a predetermined angle θ with respect to a driving direction are attached by one side (inner end surface) to both sides of a central drive frame unit 603. That is, the drive frame unit 603 corresponds to a quill, and the first dielectric elastomer actuator laminate 601-1 and the second dielectric elastomer actuator laminate 601-2 attached to the both sides of the quill correspond to outer vane and inner vane, respectively.

Further, the fixed frame unit 602 has a U-shape to support by the two opposed inner walls the other sides (outer sides) of the first dielectric elastomer actuator laminate 601-1 and the second dielectric elastomer actuator laminate 602. However, instead of the single U-shaped fixed frame unit 602 as shown in the drawing, the fixed frame unit may include two separate fixed frame units that are opposed to the surfaces of the drive frame unit 603 (however, the relative positions of the separated fixed frame units are fixed).

The operation principle of the transducer device 600 is similar to that of the transducer device 100 described above.

The position of the fixed frame unit 602 is fixed, and the drive frame unit 603 can move relative to the fixed frame unit 602. Specifically, the opposing inner walls of the U-shaped fixed frame unit 602 and the drive frame unit 603 are parallel to each other, and the drive frame unit 603 makes a translational movement in its in-plane direction as the driving direction while keeping the constant distances to the inner walls of the opposing fixed frame unit 602.

When a voltage is synchronously applied to the electrode of each of the dielectric elastomer actuators constituting the first dielectric elastomer actuator laminate 601-1 and the second dielectric elastomer actuator laminate 602, each dielectric elastomer actuators synchronously contracts in the perpendicular direction and extends in the in-plane direction. Then, the drive frame unit 603 moves relative to the fixed frame unit 602 in the driving direction inclined at the predetermined angle θ with respect to the extending direction of the dielectric elastomer actuators. The driving direction of the drive frame unit 603 is a direction parallel to the inner walls of the opposing fixed frame unit 602 (that is, a −Z direction in the drawing).

FIG. 6(A) shows the transducer device 600 before driving (a state where no voltage is applied), and FIG. 6(B) shows the transducer device 600 after driving (a state where voltage is applied). It can be understood from FIG. 6 that the drive frame unit 603 operates to protrude in the −Z direction from the leading end of the U-shaped fixed frame unit 602.

In the case of the transducer device 100 shown in FIG. 1, there is the need for providing a support structure such as a guide rail for restricting the displacement of the drive frame unit 103 in the driving direction 110. On the other hand, in the transducer device 600, the drive frame unit 603 receives the generated force of the first dielectric elastomer actuator laminate 601-1 and the second dielectric elastomer actuator laminate 602 from both sides, and thus there is no need for providing a support structure such as a guide rail that restricts the operation of the drive frame unit 603 in a predetermined driving direction.

Like the transducer device 100, the transducer device 600 also has the DEA effective cross-sectional area proportional to the longitudinal dimension L of the dielectric elastomer actuator laminates 601-1 and 601-2. Thus, increasing the dimension L makes it possible to improve the generated force. Therefore, the transducer device 600 can also efficiently obtain the output even in a limited space that is long in the driving direction but has a small cross section orthogonal to the driving direction, and can be suitably applied to an elongated mechanism such as an endoscope or an end effector of a robot arm.

Further, like the transducer device 100, the transducer device 600 has an inclination angle eθ at which the generated force can be maximized. However, the DEA effective cross-sectional area of the transducer device 600 having a feather-like structure is almost twice that of the transducer device 100 having a half-feather-like structure, and it can be expected to obtain twice the generated force.

In addition, the length L of the transducer device 600 as seen in the driving direction is preferably at least three times the minimum distance W at the place where the fixed frame unit 602 and the drive frame unit 603 sandwich the dielectric elastomer actuator laminates 601-1 and 601-2.

### Second Example

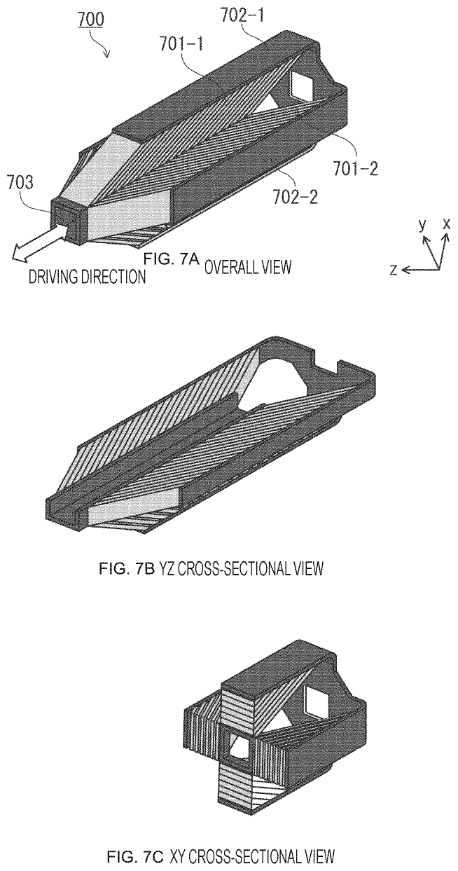

FIG. 7 shows a modified example 700 of a transducer device having a driving direction inclined at a predetermined angle θ from a direction in which dielectric elastomer actuators extend. However, FIG. 7(A) shows an overall configuration of the transducer device 700. Further, the driving direction of the transducer device 700 is defined as a Z axis, and an X axis and a Y axis are defined to be orthogonal to the Z axis. FIG. 7(B) shows a YZ cross section of the transducer device 700, and FIG. 7(C) shows an XY cross section of the transducer device 700.

The transducer device 700 includes a quadrangular prism-shaped drive frame unit 703, four fixed frame units 702-1, 702- 2, . . . opposing to each side surface of the quadrangular prism, and four dielectric elastomer actuator laminates 701-1, 701-2, . . . with both ends supported by each side surface of the drive frame unit 703 and the opposing fixed frame units 702-1, 702-2, . . . The drive frame unit 703 has a central axis of the quadrangular prism as a driving direction.

Each of the dielectric elastomer actuator laminates 701-1, 701-2, . . . has a half-feather-like structure of almost the same shape in which a plurality of rectangular dielectric elastomer actuators is laminated and attached to the drive frame unit 703 with an inclination at a predetermined angle θ with respect to the driving direction (the Z direction).

In the example shown in the drawing, the fixed frame units 702-1, 702-2, . . . constitute an integral component connected together at the back side in the drawing. For example, the fixed frame units 702-1, 702-2, . . . can be formed by bending a cross-shaped sheet metal. As a matter of course, the fixed frame units 702-1, 702-2, . . . may be configured as individual parts. In addition, the drive frame unit 703 can be reduced in weight by forming the drive frame unit 703 in a hollow square prism shape.

The operation principle of the transducer device 700 is similar to that of the transducer device 600 described above.

The positions of the fixed frame units 702- 1, 702- 2, . . . are fixed, and the drive frame unit 703 can move relative to the fixed frame units 702- 1, 702- 2, . . . surrounding the four sides in the Z direction. Specifically, each side surface of the drive frame unit 703 is arranged in parallel to the fixed frame units 702- 1, 702- 2, . . . , and makes a translational movement in the Z direction as the driving direction while keeping constant distances to the fixed frame units 702- 1, 702- 2, . . .

When a voltage is synchronously applied to the electrode of each of the dielectric elastomer actuators constituting the dielectric elastomer actuator laminates 701- 1, 701- 2, . . . , each dielectric elastomer actuators synchronously contracts in the perpendicular direction and extends in the in-plane direction. Then, the drive frame unit 703 moves relative to the fixed frame units 702- 1, 702- 2, . . . in the driving direction (the Z direction) inclined at the predetermined angle θ with respect to the extending direction of the dielectric elastomer actuators. The drive frame unit 703 performs an operation of appearing and disappearing from the leading ends of the fixed frame units 702-1, 702-2, . . . surrounding the four sides.

In the case of the transducer device 100 shown in FIG. 1, there is the need for providing a support structure such as a guide rail for restricting the displacement of the drive frame unit 103 in the driving direction 110. On the other hand, in the case of the transducer device 700, the drive frame unit 703 receives the generated force of the dielectric elastomer actuator laminates 701-1, 701-2, . . . at respective side surfaces from the four sides. Thus, there is no need for a support structure such as a guide rail that restricts the operation of the drive frame unit 703 in a predetermined driving direction, that is, the Z direction.

Like the transducer device 100, the transducer device 700 has the DEA effective cross-sectional area proportional to the longitudinal dimension of the dielectric elastomer actuator laminates 701-1, 701-2, . . . .Thus, increasing the longitudinal dimension makes it possible to improve the generated force. Therefore, the transducer device 700 can also efficiently obtain the output even in a limited space that is long in the driving direction but has a small cross section orthogonal to the driving direction, and can be suitably applied to an elongated mechanism such as an endoscope or an end effector of a robot arm.

In addition, the transducer device 700 has an inclination angle θ at which the generated force can be maximized, like the transducer device 100 having a half-feather-like structure and the transducer device 600 having a feather-like structure. However, in the transducer device 700, the number of dielectric elastomer actuators used per unit length is twice that of the transducer device 600 having a feather-like structure, and its DEA effective cross-sectional area is almost twice that of the transducer device 600 having a feather-like structure. Therefore, the transducer device 700 can be expected to obtain a generated force twice that of the transducer device 600 having a feather-like structure.

In addition, the length L of the transducer device 700 as seen in the driving direction is preferably at least three times the minimum distance W at the place where the fixed frame unit 702 and the drive frame unit 703 sandwich the dielectric elastomer actuator laminates 701-1, 701-2, . . .

Further, although not shown in the drawings or described in detail herein, a similar transducer device can be configured such that a drive frame unit is formed in the shape of a prism (N-facet prism) such as a pentagonal prism other than a quadrangular prism, a plurality of fixed frame units is opposed to each outer wall surface of the drive frame unit, and both ends of N dielectric elastomer actuator laminates are supported by the outer wall surfaces of the drive frame unit and the opposing fixed frame units. However, each dielectric elastomer actuator laminate has a half-feather-like structure attached while being inclined at a predetermined angle θ with respect to the driving direction of the drive frame unit.

### Third Example

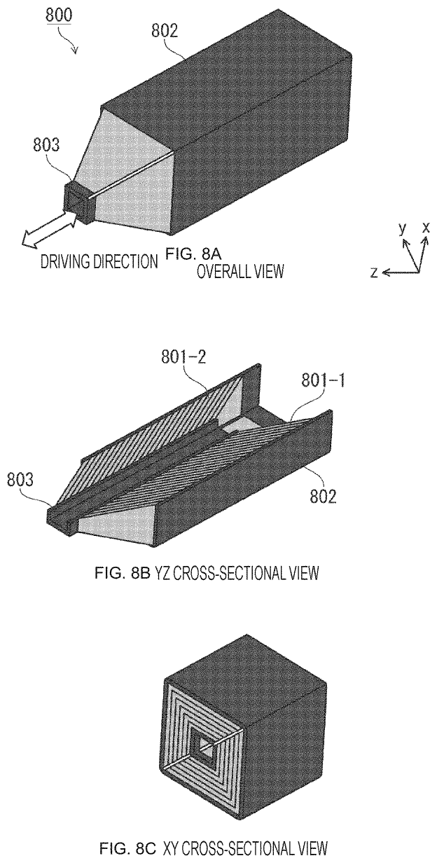

FIG. 8 shows another modified example 800 of a transducer device having a driving direction inclined at a predetermined angle θ from a direction in which dielectric elastomer actuators extend. However, FIG. 8(A) shows the overall configuration of the transducer device 800. Further, the driving direction of the transducer device 800 is defined as a Z axis, and an X axis and a Y axis are defined to be orthogonal to the Z axis. FIG. 8(B) shows a YZ cross section of the transducer device 800, and FIG. 8(C) shows an XY cross section of the transducer device 800.

The transducer device 800 has a quadrangular prism-shaped drive frame unit 803, a hollow quadrangular prism-shaped fixed frame unit 804 that accommodates the drive frame unit 803, and four dielectric elastomer actuator laminates 801- 1, 801- 2, . . . , with both ends supported by each outer wall surface of the drive frame unit 803 and inner wall surfaces of the opposing fixed frame unit 802.

The drive frame unit 803 is disposed inside the fixed frame unit 802 so that center axes of the fixed frame unit 802 and the drive frame unit 803 coincide with each other. Also, the drive frame unit 803 has a central axis of the quadrangular prism as a driving direction. In addition, the drive frame unit 803 can be reduced in weight by forming the drive frame unit 803 in a hollow square prism shape.

Each of the dielectric elastomer actuator laminates 801-1, 801-2, . . . has a half-feather-like structure of almost the same shape and are attached to the drive frame unit 803 with an inclination at a predetermined angle θ with respect to the driving direction (the Z direction). In addition, one dielectric elastomer actuator constituting the dielectric elastomer actuator laminates 801-1, 801-2, . . . has a trapezoidal shape in which one side supported by the outer wall surface of the drive frame unit 803 as an upper base and has one side instructed by the inner wall surface of the opposing fixed frame unit 802 as a lower base.

The operation principle of the transducer device 800 is similar to that of the transducer device 700 described above. The position of the fixed frame unit 802 is fixed, and the drive frame unit 803 can move relative to the fixed frame unit 802 in the Z direction which is the central axis of the quadrangular prism. When a voltage is synchronously applied to the electrode of each of the dielectric elastomer actuators constituting the dielectric elastomer actuator laminates 801-1, 801-2, . . . , each dielectric elastomer actuators synchronously contracts in the perpendicular direction and extends in the in-plane direction. Then, the drive frame unit 803 moves relative to the fixed frame units 802 in the driving direction (the Z direction) inclined at the predetermined angle θ with respect to the extending direction of the dielectric elastomer actuators. The drive frame unit 803 performs an operation of appearing and disappearing from the leading end of the hollow fixed frame unit 802.

The drive frame unit 803 receives by each wall surface the generated force of the dielectric elastomer actuator laminates 801-1, 801-2, . . . from the four sides. Therefore, the transducer device 800 does not require a support structure such as a guide rail that regulates the operation of the drive frame unit 803 in a predetermined driving direction, that is, the Z direction.

Like the transducer device 700, the transducer device 800 has the DEA effective cross-sectional area proportional to the longitudinal dimension of the dielectric elastomer actuator laminates 801-1, 801-2, . . . . Thus, increasing the longitudinal dimension makes it possible to improve the generated force. Therefore, the transducer device 800 can also efficiently obtain the output even in a limited space that is long in the driving direction but has a small cross section orthogonal to the driving direction, and can be suitably applied to an elongated mechanism such as an endoscope or an end effector of a robot arm.

In addition, with the dielectric elastomer actuator laminates 801-1, 801-2, . . . of half-feather-like structure, the transducer device 800 has the inclination angle θ at which the generated force can be maximized. The dielectric elastomer actuators constituting the dielectric elastomer actuator laminates 801-1, 801-2, . . . are formed in a trapezoidal. As can be seen from FIG. 8(B) and FIG. 8(C), the gap between the fixed frame unit 802 and the drive frame unit 803 is almost filled with each of the dielectric elastomer actuator laminates 801- 1, 801- 2, . . . . Therefore, the DEA effective cross-sectional area of the transducer device 800 is larger than that of the transducer device 700 with the rectangular dielectric elastomer actuators, and is expected to be improved in the generated force accordingly.

Here, the generated force of the transducer device 800 will be considered.

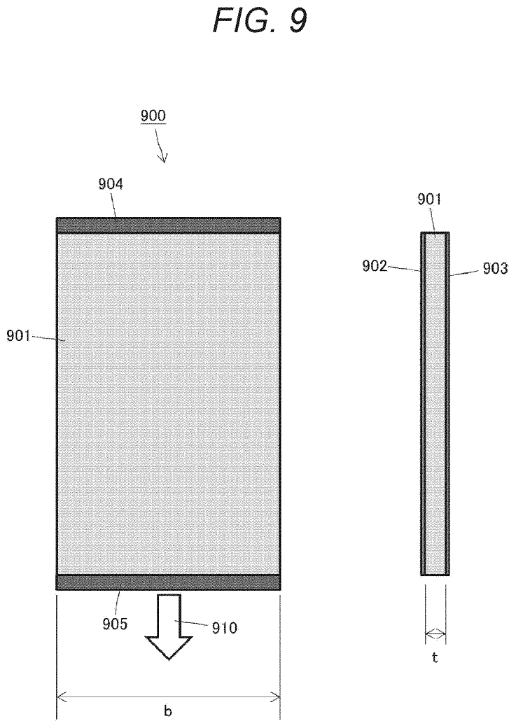

FIG. 9 shows a rectangular dielectric elastomer actuator 900. The dielectric elastomer actuator 900 includes a dielectric elastomer sheet 901 having a width b and a thickness t (i.e., a cross-sectional area of b×t), following electrodes 902 and 903 formed on both surfaces of the dielectric elastomer sheet 901, a fixed frame unit 904 attached to an upper end edge of the dielectric elastomer sheet 901, and a drive frame unit 905 attached to a lower end edge of the dielectric elastomer sheet 901. In the dielectric elastomer actuator 900, the direction indicated by reference numeral 910 in which the drive frame unit 905 is separated from the fixed frame unit 904 is defined as the driving direction.

When a voltage is applied between the following electrodes 902 and 903, the dielectric elastomer sheet 901 contracts in the perpendicular direction and extends in the driving direction 910 which is the in-plane direction. when the generated stress of the dielectric elastomer actuator 900 at this time is designated as Pₑₗ, an initial generated force F is as shown in the following equation (4):

[Equation 4]

F=b·t·Pₑₗ (4)

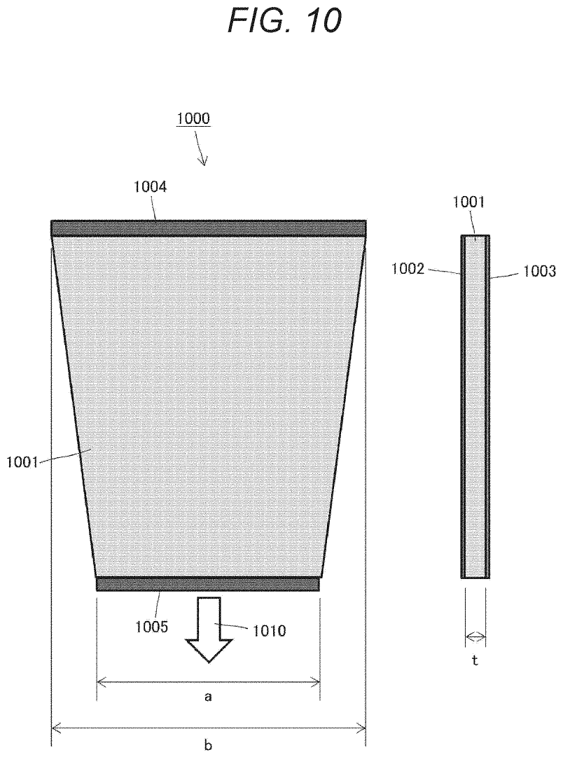

On the other hand, FIG. 10 shows a trapezoidal dielectric elastomer actuator 1000. The dielectric elastomer actuator 1000 includes a dielectric elastomer sheet 1001 having an upper base a, a lower base b, and a thickness t, following electrodes 1002 and 1003 formed on both surfaces of the dielectric elastomer sheet 1001, a fixed frame unit 1004 attached to the lower base of the dielectric elastomer sheet 1001, and a drive frame unit 1005 attached to the upper base of the dielectric elastomer sheet 1001. In the dielectric elastomer actuator 1000, the direction indicated by reference numeral 1010 in which the drive frame unit 1005 is separated from the fixed frame unit 1004 is defined as the driving direction.

When a voltage is applied between the following electrodes 1002 and 1003, the dielectric elastomer sheet 1001 contracts in the perpendicular direction and extends in the driving direction 1010 which is the in-plane direction. When the generated stress of the dielectric elastomer sheet 1001 at this time is designated as Pₑₗ, an initial generated force F of the dielectric elastomer actuator 1000 is as shown in the following equation (5):

$$[ Equation 5 ]$$

$$F = \frac{( b - a ) \cdot t \cdot {P}_{el}}{ln b - ln a} \qquad ( 5 )$$

In the case of the transducer device 800, the dielectric elastomer actuator 1000 as shown in FIG. 10 is attached to the drive frame unit 803 with an inclination at a predetermined angle θ. In consideration of the inclination θ of the sheet, when the dielectric elastomer actuator 1000 extends in the in-plane direction, a component force of the generated force in the driving direction 1010 acts on the drive frame unit 803.

Therefore, the force F of the single trapezoidal dielectric elastomer actuator 1000 acting on the drive frame unit 803 in the driving direction, that is, the Z direction is as shown in the following equation (6):

$$[ Equation 6 ]$$

$$F = \frac{( b - a ) \cdot t \cdot {P}_{el}}{ln b - ln a} cos θ \qquad ( 6 )$$

Assuming that each of the dielectric elastomer actuator laminates 801-1, 801-2, . . . includes n trapezoidal dielectric elastomer actuators 1000, each of the dielectric elastomer actuator laminates 801-1, 801-2, . . . generates a force that is n times the generated force shown in the equation (6) above. Then, as shown in FIG. 8, a resultant force of the generated forces of the respective dielectric elastomer actuator laminates 801-1, 801-2, . . . attached to the respective four inner walls acts on the quadrangular prism-shaped drive frame unit 803 in the driving direction, that is, the Z direction. Therefore, the resultant force Fₐₗₗ acting on the drive frame unit 803 is as shown in the following equation (7):

$$[ Equation 7 ]$$

$${F}_{all} = 4 n \cdot \frac{( b - a ) \cdot t \cdot {P}_{el}}{ln b - ln a} cos θ \qquad ( 7 )$$

The length L of the transducer device 800 as seen in the driving direction is preferably at least three times the minimum distance W at the place where the fixed frame unit 802 and the drive frame unit 803 sandwich the dielectric elastomer actuator laminates 801-1, 801-2, . . . .

Note that, although not shown in the drawings or described in detail herein, a similar transducer device can be formed by a drive frame unit and a fixed frame unit in the shape of a prism (N-facet prism) such as a pentagonal prism other than a quadrangular prism, and N dielectric elastomer actuator laminates with both ends supported by each outer wall surface of the drive frame unit and inner walls of the opposing fixed frame unit. However, each dielectric elastomer actuator laminate has a half-feather-like structure attached while being inclined at a predetermined angle θ with respect to the driving direction of the drive frame unit. In addition, the DEA effective area can be increased to improve the generated force by using dielectric elastomer actuator laminates in which trapezoidal dielectric elastomer actuators are laminated to fill the gap between the fixed frame unit and the drive frame unit in accordance with the prism shape.

### Fourth Example

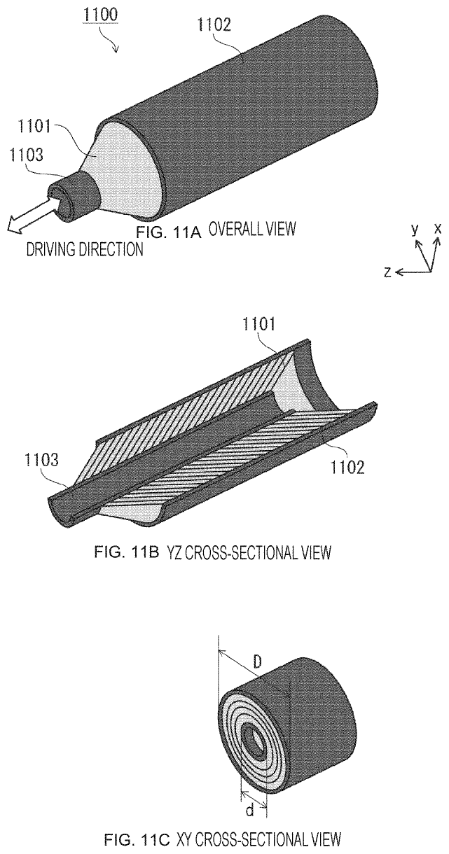

FIG. 11 shows another modified example 1100 of a transducer device having a driving direction inclined at a predetermined angle θ from a direction in which dielectric elastomer actuators extend. However, FIG. 11(A) is a perspective view of an overall configuration of the transducer device 1100. Further, the driving direction of the transducer device 1100 is defined as a Z axis, and an X axis and a Y axis are defined to be orthogonal to the Z axis. FIG. 11(B) shows a YZ cross section of the transducer device 1100, and FIG. 11(C) shows an XY cross section of the transducer device 1100.

The transducer device 1100 has a cylindrical drive frame unit 1103, a hollow cylindrical fixed frame unit 1104 that accommodates the drive frame unit 1103, and a dielectric elastomer actuator laminate 1101 with both end edges supported by an outer peripheral surface of the drive frame unit 1103 and an inner peripheral surface of the fixed frame unit 1102. The fixed frame unit 1102 and the drive frame unit 1103 are arranged so that their center axes coincide with each other. The drive frame unit 1103 can be reduced in weight by forming the drive frame unit 1103 in a hollow cylindrical shape. The outer diameter of the drive frame unit 1103 is designated d, and the inner diameter of the fixed frame unit 1102 as D.

In addition, the dielectric elastomer actuator laminate 1101 is formed by laminating a plurality of truncated cone-shaped dielectric elastomer actuators in a central axis direction. The truncated cone is a solid body obtained by cutting the cone along a plane parallel to the bottom surface and excluding the small cone portion.

The central axis of the dielectric elastomer actuator laminate 1101 is assumed to coincide with the central axis (or driving direction) of the drive frame unit 1103. By setting the diameter of the upper base of the truncated cone as d, the diameter of the home as D, and appropriately setting the height H, the dielectric elastomer actuator laminate 1101 is supported by the drive frame unit 1103 on the inner periphery and supported by the fixed frame unit on the outer periphery, and is attached with an inclination at a predetermined angle θ with respect to the driving direction (Z direction) of the drive frame unit 1103. As can be seen from FIG. 11(B), the YZ section of the transducer device 1100 has a feather-like structure.

The operation principle of the transducer device 1100 is similar to that of the transducer device 800 described above. The position of the fixed frame unit 1102 is fixed, and the drive frame unit 1103 can move relative to the fixed frame unit 1102 in the Z direction which is the central axis of the cylinder. When a voltage is synchronously applied to the electrode of each of the dielectric elastomer actuators constituting the dielectric elastomer actuator laminate 1101, each dielectric elastomer actuators synchronously contracts in the perpendicular direction and extends in the in-plane direction. Then, the drive frame unit 1103 moves relative to the fixed frame units 1102 in the driving direction (the Z direction) inclined at the predetermined angle θ with respect to the extending direction of the dielectric elastomer actuators. The drive frame unit 1103 performs an operation of appearing and disappearing from the leading end of the hollow fixed frame unit 1102.

The drive frame unit 1103 receives the generated force of the dielectric elastomer actuator laminate 1101 over the entire inner periphery. Therefore, the transducer device 1100 does not require a support structure such as a guide rail that regulates the operation of the drive frame unit 1103 in a predetermined driving direction, that is, the Z direction.

Like the transducer device 800, the transducer device 1100 has the DEA effective cross-sectional area proportional to the longitudinal dimension of the dielectric elastomer actuator laminate 1101. Thus, increasing the longitudinal dimension makes it possible to improve the generated force. Therefore, the transducer device 1100 can also efficiently obtain the output even in a limited space that is long in the driving direction but has a small cross section orthogonal to the driving direction, and can be suitably applied to an elongated mechanism such as an endoscope or an end effector of a robot arm. In addition, the transducer device 1100 is effective in a case where the space that can be occupied has a cylindrical shape.

In addition, with the dielectric elastomer actuator laminate 1101 having the YZ section of half-feather-like structure, the transducer device 1100 has the inclination angle θ at which the generated force can be maximized. The dielectric elastomer actuators constituting the dielectric elastomer actuator laminate 110 has a conical shape. As can be seen from FIG. 11(B) and FIG. 11(C), the gap between the fixed frame unit 1102 and the drive frame unit 1103 is almost filled with the dielectric elastomer actuator laminate 1101. Therefore, the DEA effective cross-sectional area of the transducer device 1100 is larger than that of the transducer device 700 with the rectangular dielectric elastomer actuators, and is expected to be improved in the generated force accordingly.

Here, the generated force of the transducer device 1100 will be considered.

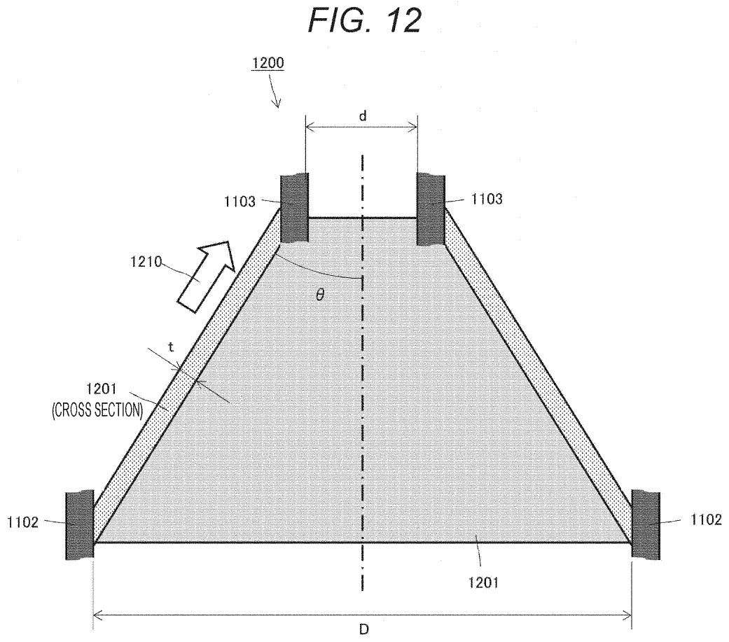

FIG. 12 shows a cross-sectional structure of a single dielectric elastomer actuator 1200 constituting the dielectric elastomer actuator laminate 1101. The dielectric elastomer actuator 1200 includes a hollow truncated cone-shaped dielectric elastomer sheet 1201 having a thickness t. Although not shown in the drawing, following electrodes are formed on the inner periphery and outer periphery of the dielectric elastomer sheet 1201, and a voltage is applied between the inner periphery and the outer periphery of the dielectric elastomer sheet 1201. In addition, the truncated cone has a shape in which the small cone portion at the tip of the cone is cut off, the inner end edge of the dielectric elastomer sheet 1201 is supported by the drive frame unit 1103, and the outer end edge of the dielectric elastomer sheet 1201 is supported by the fixed frame unit 1102. The outer diameter of the dielectric elastomer sheet 1201 (the diameter of the lower base of the truncated cone) corresponds to the inner diameter D of the fixed frame unit 1102, and the inner diameter of the dielectric elastomer sheet 1201 (the diameter of the upper base of the truncated cone) corresponds to the outer diameter d of the drive frame unit 1103. Further, the dielectric elastomer sheet 1201 (in-plane direction thereof) is inclined at a predetermined angle θ with respect to the driving direction (center axis direction) of the drive frame unit 1103.

When a voltage is applied between the following electrodes (not illustrated) on both sides of the dielectric elastomer sheet 1201, the dielectric elastomer sheet 1201 contracts in the perpendicular direction and extends in the in-plane direction indicated by reference numeral 1210. When the generated stress of the dielectric elastomer sheet 1201 at this time is designated as Pₑₗ, an initial generated force of the dielectric elastomer actuator 1200 in the in-plane direction 1210 is as shown in the following equation (8):

$$[ Equation 8 ]$$

$$F = \frac{( D - d ) \cdot π \cdot t \cdot {P}_{el}}{ln D - ln d} \qquad ( 8 )$$

The dielectric elastomer sheet 1201 is attached to the drive frame unit 1103 with an inclination at a predetermined angle θ. In consideration of the inclination θ of the sheet, when the dielectric elastomer sheet 1201 extends in the in-plane direction 1210, a component force of the generated force in the driving direction acts on the drive frame unit 1103. Therefore, the force F of the conical dielectric elastomer actuator 1200 acting on the drive frame unit 1103 in the driving direction, that is, the Z direction is as shown in the following equation (9):

$$[ Equation 9 ]$$

$$F = \frac{( D - d ) \cdot π \cdot t \cdot {P}_{el}}{ln D - ln d} cos θ \qquad ( 9 )$$

Assuming that the dielectric elastomer actuator laminate 1101 includes n dielectric elastomer actuators 1200, the dielectric elastomer actuator laminate 1101 generates a force that is n times the generated force shown in the above equation (9). This force acts in the driving direction of the drive frame unit 1103. Therefore, the resultant force Fₐₗₗ acting on the drive frame unit 803 is as shown in the following equation (10):

$$[ Equation 10 ]$$

$${F}_{all} = n \frac{( D - d ) \cdot π \cdot t \cdot {P}_{el}}{ln D - ln d} cos θ \qquad ( 10 )$$

In addition, the length L of the transducer device 1100 as seen in the driving direction is preferably at least three times the minimum distance W at the place where the fixed frame unit 1102 and the drive frame unit 1103 sandwich the dielectric elastomer actuator laminate 1101.

### Fifth Example

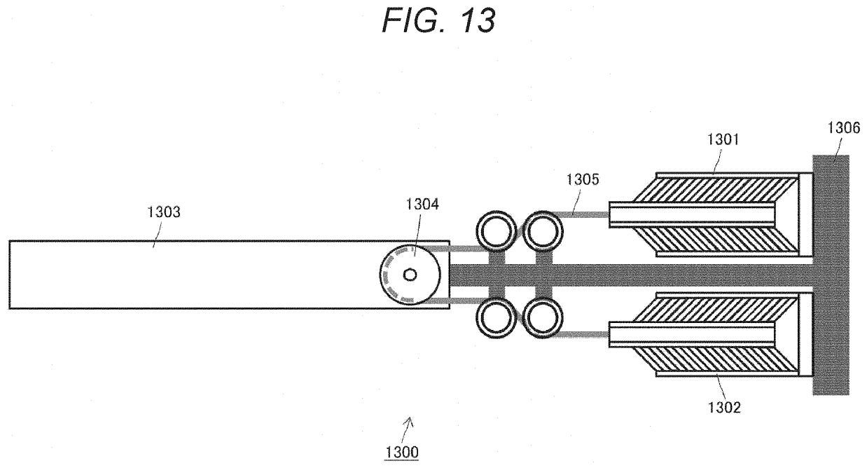

FIG. 13 is a diagram showing a configuration example 1300 of a joint bending mechanism that has a transducer device driven by dielectric elastomer actuator laminates having a feather-like structure.

The illustrated joint bending mechanism 1300 includes two opposing transducer devices 1301 and 1302 installed on a T-shaped base unit 1306, a joint (pulley) 1304 that supports a rod-shaped arm 1303 so as to be rotatable with respect to a leading end of the base unit 1306, and a single wire 1305 for traction. Each of the transducer devices 1301 and 1302 has a fixed frame unit fixed on the base unit 1306. Further, the arm 1303 and the pulley 1304 rotate integrally.

Each of the transducer devices 1301 and 1302 may be any one of the above-described transducer devices 100, 600, 700, 800, and 1100 using dielectric elastomer actuator laminates of a half-feature-like structure or a feather-like structure.

The wire 1305 is wound around an outer periphery of the pulley 1304, and is attached to leading ends of the respective drive frame units of the transducer devices 1301 and 1302 of which both ends are opposed to each other.

Here, in a state where each of the transducer devices 1301 and 1302 is not driven (that is, a state where no voltage is applied to the dielectric elastomer actuators), while the wire 1305 is forcibly extended, the fixed frame unit of each of the transducer devices 1301 and 1302 is attached to the base unit 1306, thereby increasing and adjusting initial tension of the wire 1305. When each of the transducer devices 1301 and 1302 is not driven, the tension of the wires 1305 is balanced between the transducer devices 1301 and 1302.

Then, when a voltage is applied to either one of the transducer devices 1301 and 1302, the drive frame unit of the transducer device 1301 or 1302 to which the voltage is applied is displaced in the driving direction (the leftward direction in FIG. 13). As a result, the tension of the wire 1305 between the transducer devices 1301 and 1302 becomes imbalanced, and the wire 1305 is pulled toward the non-driven transducer device. Such a tractive force of the wire 1305 can allow rotation of the pulley 1304 and driving of the arm 1303.

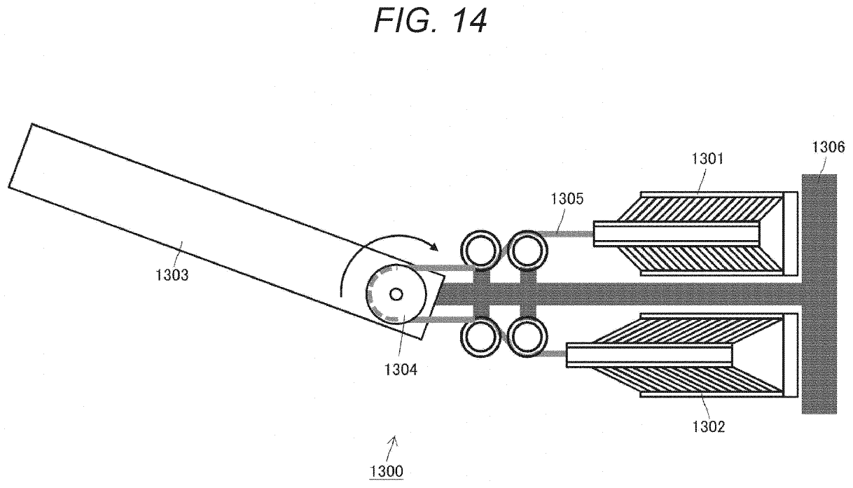

In the example shown in FIG. 14, a voltage is applied to the transducer device 1302, the drive frame unit is displaced in the driving direction (the leftward direction in FIG. 14), and the wire 1305 is pulled toward the transducer device 1301. Then, the pulley 1304 rotates in the clockwise direction in the drawing by the tractive force of the wire 1305, and the leading end of the arm 1303 is raised accordingly.

Basically, a voltage is applied to only one of the transducer devices 1301 and 1302 such that the transducer devices perform operations opposite to each other simultaneously. In this manner, the arm 1303 can be driven by rotating the joint 1304 clockwise or counterclockwise.

The joint bending mechanism as shown in FIGS. 13 and 14 can be applied to, for example, forceps used in a surgical operation, a robot prosthesis, or the like.

### Sixth Example

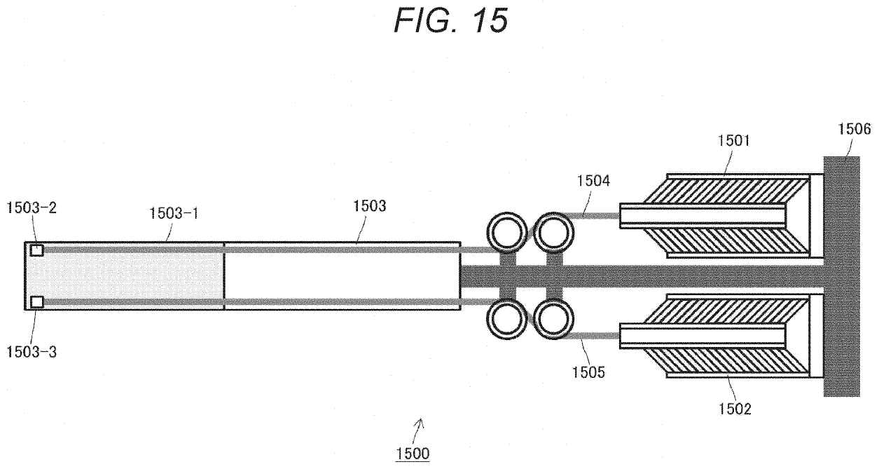

FIG. 15 is a diagram showing a configuration example 1500 of a bending mechanism that has a transducer device driven by dielectric elastomer actuator laminates of a feather-like structure.

The illustrated bending mechanism 1500 includes two opposing transducer devices 1501 and 1502 installed on a T-shaped base unit 1506, a longitudinal bending portion 1503 attached to a leading end of the base unit 1506, and wires 1504 and 1505 for traction. Each of the transducer devices 1501 and 1502 has a fixed frame unit fixed on the base unit 1506. In addition, the bending portion 1503 has an elastic body 1503-1 at a leading end that is deformable to warp in a direction orthogonal to the longitudinal side, for example.

Each of the transducer devices 1501 and 1502 may be any one of the above-described transducer devices 100, 600, 700, 800, and 1100 using dielectric elastomer actuator laminates of a half-feature-like structure or a feather-like structure.

Each of the wires 1504 and 1505 has one end attached to the drive frame unit of the transducer device 1501 and 1502, and has the other end fixed to leading ends 1503-2 and 1503-3 of the bending portion 1503. As shown in the figure, the wire 1504 and the wire 1505 are each extended substantially in parallel along the opposite longitudinal sides of the bending portion 1503.

Here, in a state where the respective transducer devices 1501 and 1502 are not driven (that is, a state where no voltage is applied to the dielectric elastomer actuators), while the respective wires 1504 and 1505 are forcibly extended, the fixed frame units of the transducer devices 1501 and 1502 are attached to the base unit 1506, thereby increasing and adjusting initial tension of the wires 1504 and 1505. When the transducer devices 1501 and 1502 are not driven, the initial tensions of the wires 1504 and 1505 are increased and adjusted. The tensions of the transducer devices 1501 and 1502 are balanced.

Then, when a voltage is applied to either one of the transducer devices 1501 and 1502, the drive frame unit of the transducer device 1501 or 1502 to which the voltage is applied is displaced in the driving direction (the leftward direction in FIG. 15). As a result, the balance of tension between the wires 1504 and 1505 is lost, and the wire 1504 or 1505 attached to the transducer device that is not driven pulls the leading end of the bending portion 1503. Accordingly, the elastic body 1503-1 becomes bent.

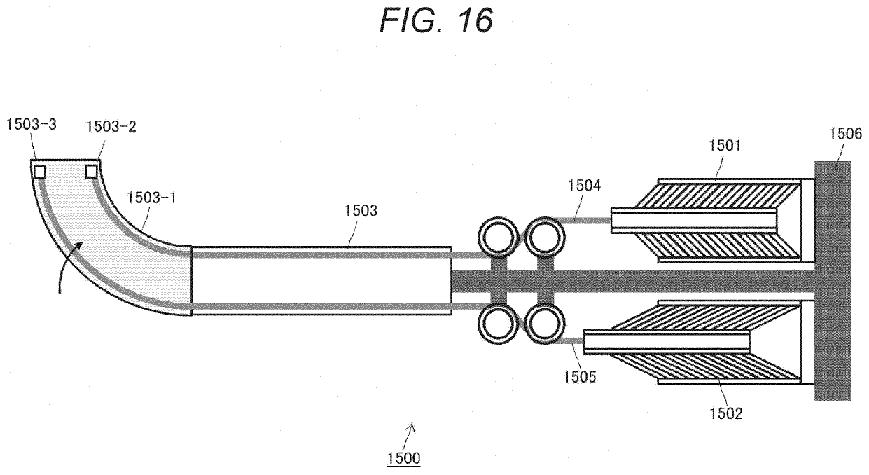

In the example shown in FIG. 16, a voltage is applied to the transducer device 1502, the drive frame unit is displaced in the driving direction (the leftward direction in FIG. 16), and the wire 1504 attached to the transducer device 1501 is pulled. Then, when one side of the elastic body 1503-1 contracts, the bending portion 1504 bends with the leading end facing upward.

Basically, a voltage is applied to only one of the transducer devices 1501 and 1502 such that the transducer devices perform operations opposite to each other simultaneously. In this manner, the bending portion 1503 can be bent with the leading end facing either the upward or downward direction of the drawing.

The bending mechanism as shown in FIGS. 15 and 16 can be applied to, for example, a flexible endoscope, or the like. Seventh example

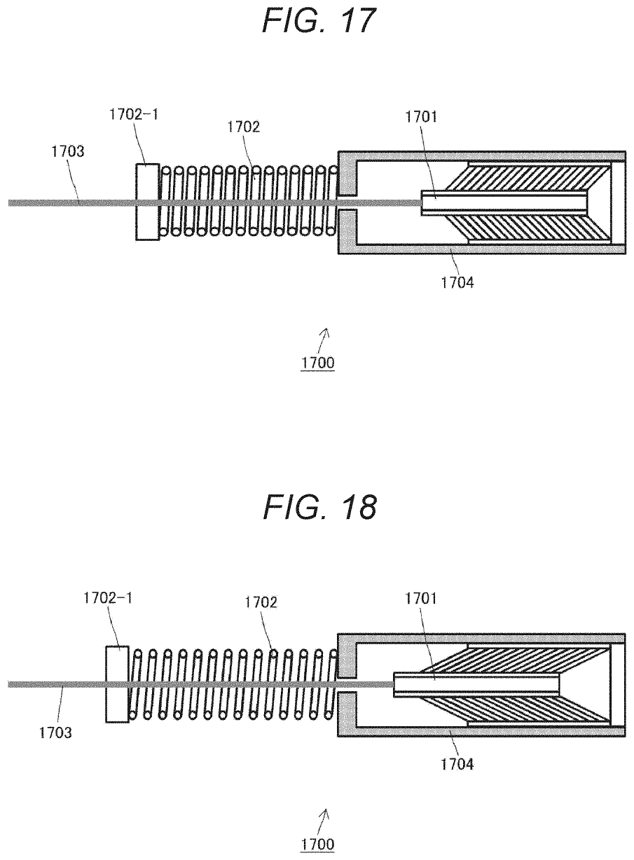

FIG. 17 is a diagram showing a configuration example 1700 of a linear actuator device that has a transducer device driven by a dielectric elastomer actuator laminate of a feather-like structure.

The illustrated linear actuator device 1700 includes one transducer device 1701, a compression coil spring 1702 connected in series to the transducer device 1701, and a single wire 1703 for traction. The transducer device 1701 is housed in a hollow case unit 1704.

The transducer devices 1701 may be any one of the above-described transducer devices 100, 600, 700, 800, and 1100 using dielectric elastomer actuator laminates of a half-feature-like structure or a feather-like structure.

The transducer device 1701 has a fixed frame unit fixed in the case unit 1704. The wire 1703 has one end attached to a leading end of a drive frame unit of the transducer device 1701. In addition, a leading end surface of the case unit 1704 has a hole through which the wire 1703 is to be inserted.

The compression coil spring 1702 is connected in series to the transducer device 1701 on the outside of the leading end surface of the case unit 1704 so that an axial direction of the coil substantially coincides with the driving direction of the transducer device 1701 (or its drive frame unit).

The wire 1703 has one end attached to the leading end portion of the drive frame unit of the transducer device 1701 and inserted through the insertion hole of the case unit 1704 and the compression coil spring 1702, and has the other end attached to a driving target (not illustrated). Further, one portion of the wire 1703 is fixed to a leading end portion 1702- 1 of the compression coil spring 1702.

Here, in a state where the transducer device 1701 is not driven (that is, a voltage is not applied to the dielectric elastomer actuator), while a compression load is applied to the compression coil spring 1702 to contract in the axial direction of the coil (that is, the driving direction of the transducer device 1701), the other end of the wire 1703 is attached to a driving target (not illustrated), thereby increasing and adjusting the initial tension of the wire 1703.

Then, when a voltage is applied to the transducer device 1701, the drive frame unit is displaced in the driving direction (the leftward direction in FIG. 17). As a result, as shown in FIG. 18, the compression coil spring 1702 that has contracted in the initial state is restored, that is, extended. The displacement amount of the end portion 1702-1 of the compression coil spring 1702 corresponds to the drive amount of the linear actuator device 1700.

As shown in FIG. 17, an initial tension in the driving direction of the transducer device 1701 is applied in advance to the wire 1703 for traction by the compression coil spring 1702. As a result, the buckling of the wire 1703 with voltage application to the transducer device 1701 (the dielectric elastomer actuators thereof) can be prevented, and the generated force can be efficiently extracted.

### Eighth Example

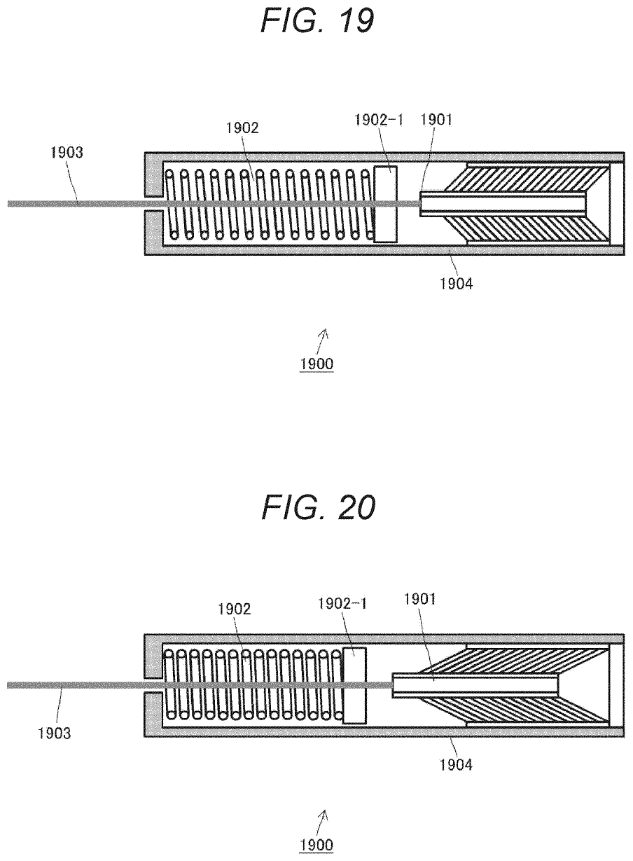

FIG. 19 is a diagram showing another configuration example 1900 of a linear actuator device that has a transducer device driven by a dielectric elastomer actuator laminate of a feather-like structure.

The illustrated linear actuator device 1900 includes one transducer device 1901, an extension coil spring 1902 connected in series to the transducer device 1901, and a single wire 1903 for traction. The transducer device 1901 and the extension coil spring 1902 are accommodated in a hollow case unit 1904.

The transducer devices 1901 may be any one of the above-described transducer devices 100, 600, 700, 800, and 1100 using dielectric elastomer actuator laminates of a half-feature-like structure or a feather-like structure.

The transducer device 1901 has a fixed frame unit fixed in the case unit 1904. The wire 1903 has one end attached to a leading end of a drive frame unit of the transducer device 1901. In addition, a leading end surface of the case unit 1904 has a hole through which the wire 1903 is to be inserted.

The extension coil spring 1902 is connected in series to the transducer device 1901 in the case unit 1904 so that an axial direction of the coil substantially coincides with the driving direction of the transducer device 1901 (or its drive frame unit).

The wire 1903 has one end attached to the leading end portion of the drive frame unit of the transducer device 1901 and inserted through the extension coil spring 1902 and the insertion hole of the case unit 1904, and has the other end attached to a driving target (not illustrated). Further, one portion of the wire 1903 is fixed to a trailing end portion 1902-1 of the extension coil spring 1902.

Here, in a state where the transducer device 1901 is not driven (that is, a voltage is not applied to the dielectric elastomer actuator), while an extension load is applied to the extension coil spring 1902 to extend in the axial direction of the coil (that is, the driving direction of the transducer device 1901), the other end of the wire 1903 is attached to a driving target (not illustrated), thereby increasing and adjusting the initial tension of the wire 1903.

Then, when a voltage is applied to the transducer device 1901, the drive frame unit is displaced in the driving direction (the leftward direction in FIG. 19). As a result, as shown in FIG. 20, the tension coil spring 1902 that has contracted in the initial state is restored, that is, extended. The displacement amount of the end portion 1902-1 of the extension coil spring 1902 corresponds to the drive amount of the linear actuator device 1900.

As shown in FIG. 19, an initial tension in the driving direction of the transducer device 1901 is applied in advance to the wire 1903 for traction by the extension coil spring 1902. As a result, the buckling of the wire 1903 with voltage application to the transducer device 1901 (the dielectric elastomer actuators thereof) can be prevented, and the generated force can be efficiently extracted.

### Ninth Example

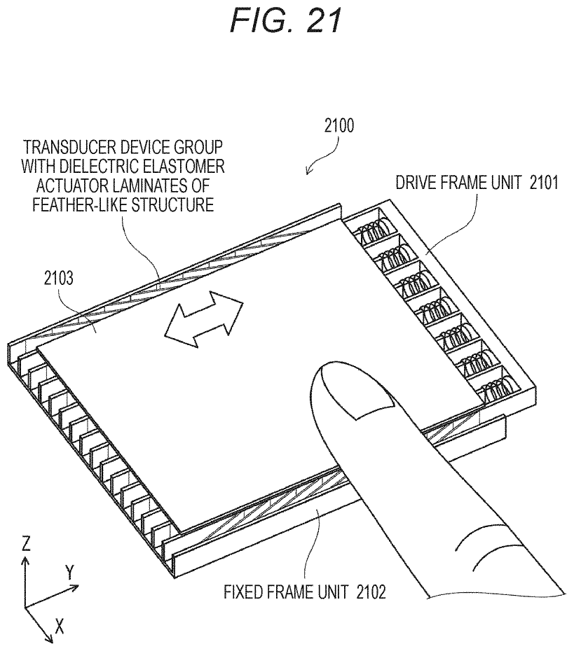

FIG. 21 is a diagram showing a configuration example 2100 of a vibration presentation device that has transducer devices driven by dielectric elastomer actuator laminates of a feather-like structure.

The illustrated vibration presentation device 2100 is formed by arranging a plurality of dielectric elastomer actuator laminates in parallel such that their respective driving directions are parallel and are the same driving direction (Y direction in FIG. 21). The vibration presentation device 2100 may be formed by using any of the transducer devices 100, 600, 700, 800, and 1100 described above.

All the transducer devices arranged in parallel has an integrated drive frame unit, and also has an integrated fixed frame unit.

Specifically, the fixed frame unit 2102 includes a plurality of groove-like guide rails that regulates the driving directions of the transducer devices in one direction such that one transducer device is accommodated in each guide rail. The opposing inner walls of the guide rails support one each end of the dielectric elastomer actuators laminated in a feather-like structure.

On the other hand, the drive frame unit 2101 has a comb shape, and each of the comb teeth is inserted into the guide rails on the fixed frame unit 2102 to support the other ends of the dielectric elastomer actuators laminated in a feather-like structure. In addition, a compression spring is disposed in each valley of the comb to apply an initial tension in advance so that the fixed frame unit 2102 pulls the drive frame unit 2101 in the direction opposite to the driving direction.

Therefore, when a voltage is synchronously applied to each dielectric elastomer actuator, each of the comb teeth of the drive frame unit is pushed out from the guide rails on the fixed frame unit 2102. Accordingly, the drive frame unit 2101 is driven in the Y direction to move in and out of the leading end of the fixed frame unit 2102. Since the fixed frame unit 2102 and the drive frame unit 2101 are integral units, the total generated force of the transducer devices connected in parallel becomes the generated force of the vibration presentation device 2100.

Further, when a voltage with a predetermined waveform such as a sine wave or a rectangular wave (or a voltage whose level changes in the time direction) is applied to the dielectric elastomer actuators, the drive frame unit 2101 vibrates with respect to the fixed frame unit 2102. Further, using the dielectric elastomer actuator laminates of a feather-like structure makes it possible to improve the spring constant of the mechanism in the driving direction, and achieve a resonance frequency in a high frequency band.

On the top of the vibration presentation device 2100, a plate-like operation surface 2103 is disposed to cover the components of the drive frame unit 2101. When the vibration presentation device 2100 starts vibration output while a person touches the operation surface 2103 with a fingertip or the like, a tactile stimulus can be given to the person. Therefore, the vibration presentation device 2100 can be used as a haptic device of an information processing apparatus.

### Tenth Example

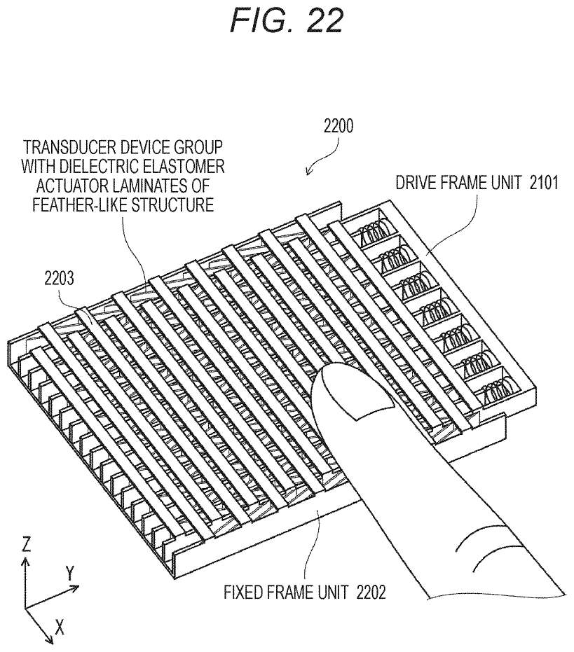

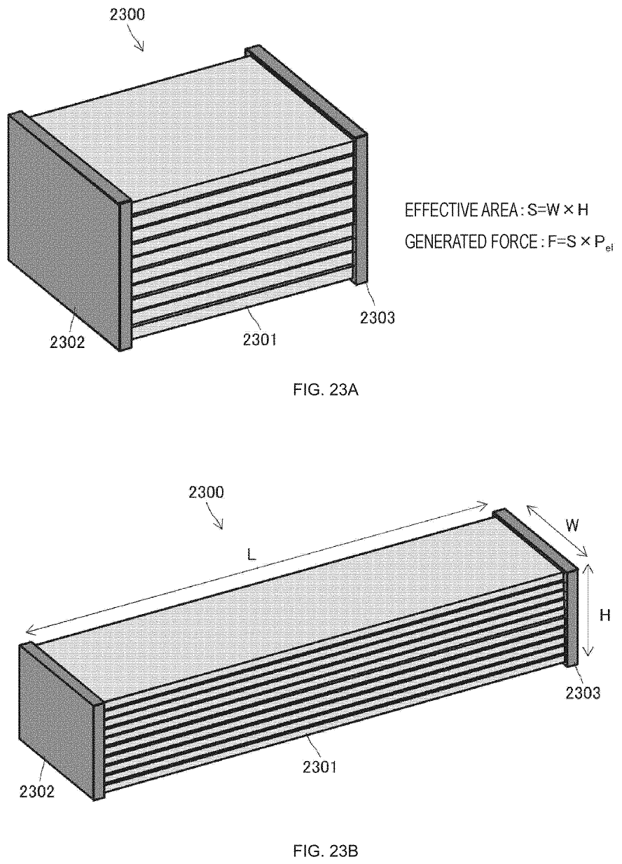

FIG. 22 is a diagram showing another configuration example 2200 of a vibration presentation device that has transducer devices driven by dielectric elastomer actuator laminates of a feather-like structure.

The illustrated vibration presentation device 2200 is formed by arranging a plurality of dielectric elastomer actuator laminates in parallel such that their respective driving directions are parallel and are the same driving direction. The vibration presentation device 2200 may be formed by using any of the transducer devices 100, 600, 700, 800, and 1100 described above.

All the transducer devices arranged in parallel has an integrated drive frame unit, and also has an integrated fixed frame unit.

Specifically, the fixed frame unit 2202 includes a plurality of groove-like guide rails that regulates the driving direction of each of the transducer devices in one direction and one transducer device is accommodated in each guide rail. The opposing inner walls of the guide rails support one each end of the dielectric elastomer actuators laminated in a feather-like structure.

On the other hand, the drive frame unit 2201 has a comb shape, and each of the comb teeth is inserted into the guide rails on the fixed frame unit 2202 to support the other end of each dielectric elastomer actuator laminated in a feather-like structure. In addition, a compression spring is disposed in each valley of the comb to apply an initial tension in advance so that the fixed frame unit 2202 pulls the drive frame unit 2201 in the direction opposite to the driving direction.

Therefore, when a voltage is synchronously applied to each dielectric elastomer actuator, each of the comb teeth of the drive frame unit is pushed out from the guide rails on the fixed frame unit 2202. Accordingly, the drive frame unit 2201 is driven in the Y direction to move in and out of the leading end of the fixed frame unit 2202. Since the fixed frame unit 2202 and the drive frame unit 2201 are integral units, the total generated force of the transducer devices connected in parallel becomes the generated force of the vibration presentation device 2200.

Further, when a voltage with a predetermined waveform such as a sine wave or a rectangular wave (or a voltage whose level changes in the time direction) is applied to each dielectric elastomer actuator, the drive frame unit 2201 vibrates with respect to the fixed frame unit 2202. Further, using the dielectric elastomer actuator laminates of a feather-like structure makes it possible to improve the spring constant of the mechanism in the driving direction, and achieve a resonance frequency in a high frequency band.

An operation surface 2203 disposed on the top of the vibration presentation device 2200 has gridiron gaps. Accordingly, parts of the drive frame unit 2201 are partially exposed. When the vibration presentation device 2200 starts vibration output while a person touches the operation surface 2203 with a fingertip or the like, a tactile stimulus can be given to the person. The person partially touches the internal part through the gridiron gaps in the operation surface 2203. This makes it possible to give a stronger tactile stimulus than the vibration presentation device 2100 shown in FIG. 21. Therefore, the vibration presentation device 2200 can be used as a haptic device of an information processing apparatus.

### INDUSTRIAL APPLICABILITY

The technique disclosed herein has been described in detail so far with reference to specific embodiments. However, it is obvious that persons skilled in the art can achieve modifications and replacements of the embodiments without deviating from the gist of the technique disclosed herein.

A transducer device to which the technology disclosed herein is applied can efficiently obtain an output even in a limited space where the driving direction is long but the cross-sectional size perpendicular to the driving direction is small. Therefore, for example, the transducer device can be suitably applied to an elongated mechanism such as an endoscope or an end effector of a robot arm.

In addition, two opposed transducer devices to which the technology disclosed herein is applied, for example, can be used to drive a forceps used in a surgical operation, a joint bending mechanism used in a robot prosthesis or the like, a bending mechanism used for flexible endoscope, and others.

Arranging in parallel a plurality of transducer devices to which the technology disclosed herein is applied can form a vibration presentation device that provides tactile stimulation to a person.

A transducer device to which the technology disclosed herein is applied can be applied to various industrial fields including the medical field.

Briefly, the technique disclosed herein has been described in the form of exemplification, and thus the description herein should not be interpreted in a limited way. The gist of the technique disclosed herein should be interpreted with reference to the claims.

Note that the technique disclosed herein can also be configured as follows:

(1) A transducer device having a predetermined driving direction and including:

a laminate of elastomer actuators that is disposed so as to be inclined at a predetermined angle with respect to the driving direction and has a stretchable elastomer and a following electrode; and

a fixed frame unit and a drive frame unit that support the laminate.

(2) The transducer device according to (1), in which

the fixed frame unit supports one end of the laminate, and

the drive frame unit supports the other end of the laminate, faces the fixed frame unit, and is movable in the driving direction with respect to the fixed frame unit.

(3) The transducer device according to (1) or (2), in which

the drive frame unit supports each one end of first and second laminates inclined at the predetermined angle on both sides, and

the fixed frame unit supports the other ends of the first and second laminates.

(4) The transducer device according to (1) or (2), in which

the drive frame unit includes an N-facet prism (where N is an integer of 3 or more) having a central axis in the driving direction and supports any one end of the N laminates by each outer wall surface of the prism, and

the fixed frame unit supports the other ends of the N laminates.

(5) The transducer device according to (1) or (2), in which

the drive frame unit includes an N-facet prism (where N is an integer of 3 or larger) having a central axis in the driving direction, the fixed frame unit includes a hollow N-facet prism that accommodates the drive frame unit, and

each one of the N laminates is supported by each outer wall surface of the drive frame unit and an inner wall surface of the fixed frame unit opposed to the drive frame unit.

(6) The transducer device according to (5), in which the drive frame unit and the fixed frame unit are arranged so that their center axes coincide with each other.

(7) The transducer device according to (5) or (6), in which

the laminate is formed by laminating a plurality of the elastomer actuators that includes the trapezoidal elastomer and the following electrode, and

the outer wall surfaces of the drive frame unit support the laminate by one end corresponding to an upper base of the trapezoid, and the inner wall surface of the opposing fixed frame unit supports the laminate by one end corresponding to a lower base of the trapezoid.

(8) The transducer device according to (1) or (2), in which

the drive frame unit includes a cylinder having a central axis in the driving direction,

the fixed frame unit has a central axis coinciding with the drive frame unit and includes a hollow cylinder that accommodates the drive frame unit, and

the laminate is formed by laminating a plurality of the elastomers having a truncated cone shape in a central axis direction.

(9) The transducer device according to any one of (1) to (8), in which

a length in the driving direction is at least three times a minimum distance between the drive frame unit and the fixed frame unit.

(10) A joint device including:

a transducer unit that has a laminate of elastomer actuators that is disposed so as to be inclined at a predetermined angle with respect to a predetermined driving direction and includes a stretchable elastomer and a following electrode, and a fixed frame unit and a drive frame unit that support the laminate;

a transfer unit that is attached to the drive frame unit and transfers a movement operation of the drive frame unit with respect to the fixed frame unit in the driving direction; and

a movable unit that is pulled by the transfer unit.

(11) The joint device according to (10), in which

the transducer unit includes a first transducer device and a second transducer device that oppose to each other,

the transfer unit includes a wire with both ends attached to the drive frame unit of the first transducer device and the drive frame unit of the second transducer device, and

the movable unit includes a pulley around which the wire is wound and an arm that rotates integrally with the pulley.

(12) The joint device according to (10), in which

the transducer unit includes a first transducer device and a second transducer device that oppose to each other,

the transfer unit includes a first wire with one end attached to the drive frame unit of the first transducer device and a second wire with one end attached to the drive frame unit of the second transducer device, and

the movable unit includes a bending portion in which the first wire and the second wire are each extended along opposite sides in a longitudinal direction and the other ends of the first wire and the second wire are fixed to a leading end.

(13) An actuator device including:

a transducer unit that has a laminate of elastomer actuators that is disposed so as to be inclined at a predetermined angle with respect to a predetermined driving direction and includes a stretchable elastomer and a following electrode, and a fixed frame unit and a drive frame unit that support the laminate;

a wire with one end attached to the drive frame unit; and

a spring that fixes a portion of the wire and applies a predetermined tension to the wire.

### REFERENCE SIGNS LIST

100 Transducer device
101 Dielectric elastomer actuator laminate
102 Fixed frame unit
103 Drive frame unit
600 Transducer device
601-1, 600-2 Dielectric elastomer actuator laminate
602 Fixed frame unit
603 Drive frame unit
700 Transducer device
701-1, 700-2 Dielectric elastomer actuator laminate
702-1, 702-2 Fixed frame unit
703 Drive frame unit
800 Transducer device
801-1, 800-2 Dielectric elastomer actuator laminate
802 Fixed frame unit
803 Drive frame unit
900 Dielectric elastomer actuator (rectangular)
901 Dielectric elastomer sheet
902, 903 Following electrode
904 Fixed frame unit
905 Drive frame unit
1000 Dielectric elastomer actuator (trapezoidal)
1001 Dielectric elastomer sheet
1002, 1003 Following electrode
1004 Fixed frame unit
1005 Drive frame unit
1100 Transducer device
1101 Dielectric elastomer actuator laminate
1102 Fixed frame unit
1103 Drive frame unit
1300 Joint bending mechanism
1301, 1302 Transducer device
1303 Arm
1304 Joint (pulley)
1305 Wire
1306 Base unit
1500 Bending mechanism
1501, 1502 Transducer device
1503 Bending portion
1503-1 Elastic body
1504, 1505 Wire
1506 Base unit
1700 Linear actuator device
1701 Transducer device
1702 Compression coil spring
1703 Wire
1704 Case unit
1900 Linear actuator device
1901 Transducer device
1902 Extension coil spring
1903 Wire
1904 Case unit
2100 Vibration presentation device
2101 Drive frame unit
2102 Fixed frame unit
2103 Operation surface
2200 Vibration presentation device
2201 Drive frame unit
2202 Fixed frame unit
2203 Operation surface

1. A transducer device having a predetermined driving direction and comprising:
a laminate of elastomer actuators that is disposed so as to be inclined at a predetermined angle with respect to the driving direction and has a stretchable elastomer and a following electrode; and
a fixed frame unit and a drive frame unit that support the laminate.

2. The transducer device according to claim 1, wherein
the fixed frame unit supports one end of the laminate, and
the drive frame unit supports the other end of the laminate, faces the fixed frame unit, and is movable in the driving direction with respect to the fixed frame unit.

3. The transducer device according to claim 1, wherein
the drive frame unit supports each one end of first and second laminates inclined at the predetermined angle on both sides, and
the fixed frame unit supports the other ends of the first and second laminates.

4. The transducer device according to claim 1, wherein
the drive frame unit includes an N-facet prism (where N is an integer of 3 or more) having a central axis in the driving direction and supports any one end of the N laminates by each outer wall surface of the prism, and
the fixed frame unit supports the other ends of the N laminates.

5. The transducer device according to claim 1, wherein
the drive frame unit includes an N-facet prism (where N is an integer of 3 or larger) having a central axis in the driving direction,
the fixed frame unit includes a hollow N-facet prism that accommodates the drive frame unit, and
each one of the N laminates is supported by each outer wall surface of the drive frame unit and an inner wall surface of the fixed frame unit opposed to the drive frame unit.

6. The transducer device according to claim 5, wherein
the drive frame unit and the fixed frame unit are arranged so that their center axes coincide with each other.

7. The transducer device according to claim 5, wherein
the laminate is formed by laminating a plurality of the elastomer actuators that includes the trapezoidal elastomer and the following electrode, and
the outer wall surfaces of the drive frame unit support the laminate by one end corresponding to an upper base of the trapezoid, and the inner wall surface of the opposing fixed frame unit supports the laminate by one end corresponding to a lower base of the trapezoid.

8. The transducer device according to claim 1, wherein
the drive frame unit includes a cylinder having a central axis in the driving direction,
the fixed frame unit has a central axis coinciding with the drive frame unit and includes a hollow cylinder that accommodates the drive frame unit, and
the laminate is formed by laminating a plurality of the elastomers having a truncated cone shape in a central axis direction.

9. The transducer device according to claim 1, wherein
a length in the driving direction is at least three times a minimum distance between the drive frame unit and the fixed frame unit.

10. A joint device comprising:
a transducer unit that has a laminate of elastomer actuators that is disposed so as to be inclined at a predetermined angle with respect to a predetermined driving direction and includes a stretchable elastomer and a following electrode, and a fixed frame unit and a drive frame unit that support the laminate;
a transfer unit that is attached to the drive frame unit and transfers a movement operation of the drive frame unit with respect to the fixed frame unit in the driving direction; and
a movable unit that is pulled by the transfer unit.

11. The joint device according to claim 10, wherein
the transducer unit includes a first transducer device and a second transducer device that oppose to each other,
the transfer unit includes a wire with both ends attached to the drive frame unit of the first transducer device and the drive frame unit of the second transducer device, and
the movable unit includes a pulley around which the wire is wound and an arm that rotates integrally with the pulley.

12. The joint device according to claim 10, wherein
the transducer unit includes a first transducer device and a second transducer device that oppose to each other,
the transfer unit includes a first wire with one end attached to the drive frame unit of the first transducer device and a second wire with one end attached to the drive frame unit of the second transducer device, and
the movable unit includes a bending portion in which the first wire and the second wire are each extended along opposite sides in a longitudinal direction and the other ends of the first wire and the second wire are fixed to a leading end.

13. An actuator device comprising:
a transducer unit that has a laminate of elastomer actuators that is disposed so as to be inclined at a predetermined angle with respect to a predetermined driving direction and includes a stretchable elastomer and a following electrode, and a fixed frame unit and a drive frame unit that support the laminate;
a wire with one end attached to the drive frame unit; and
a spring that fixes a portion of the wire and applies a predetermined tension to the wire.
